(19) United States
(12) Patent Application Publication
(10) Pub. No.: US 2025/0132539 A1
(43) Pub. Date: Apr. 24, 2025

(54) MODE-SELECTIVE AND TUNABLE MULTI-WAVELENGTH O-BAND QUANTUM-DOT U-COMB LASER

(71) Applicant: Axalume, Inc., Cayenne Creek Rd., CA (US)

(72) Inventors: Ashok V. Krishnamoorthy, San Diego, CA (US); Yossef Ehrlichman, San Diego, CA (US); Alex Friedman, San Diego, CA (US); John Simons, San Diego, CA (US)

(73) Assignee: Axalume, Inc., San Diego, CA (US)

(21) Appl. No.: 19/001,361

(22) Filed: Dec. 24, 2024

Related U.S. Application Data
(63) Continuation-in-part of application No. 18/115,339, filed on Feb. 28, 2023.

(51) Int. Cl. H01S 5/14; H01S 5/026; H01S 5/065; H01S 5/10

(52) U.S. Cl. CPC H01S 5/142; H01S 5/0265; H01S 5/0653; H01S 5/0657; H01S 5/1096

(57) ABSTRACT

An optical source is described. This optical source may include a semiconductor laser chip and a silicon-photonics chip that provide an optical cavity. The semiconductor laser chip may provide gain at multiple lasing wavelengths in a band of wavelengths. Moreover, the silicon-photonics chip may adjust a size of an optical signal proximate to an interface between the semiconductor laser chip and the silicon-photonics chip. Furthermore, by adjusting a phase of a phase shifter and resonance frequencies of a micro-ring resonator in the silicon-photonics chip, a center frequency of a passband of the micro-ring resonator may be matched to a non-zero integer multiple of a cavity-mode spacing. This may allow the optical source to mode-lock the lasing wavelengths of the optical source by suppressing unwanted lasing wavelengths and re-enforcing the lasing wavelengths. In some embodiments, a free-spectral range of the optical source may be between 100 GHz and 800 GHz.

### CROSS REFERENCE TO RELATED APPLICATIONS

This application is a Continuation-in-Part of U.S. Non-Provisional application Ser. No. 18/115,339, “Broad Bandwidth Laser with Reduced Mode Beating,” filed on Feb. 28, 2023, by Ashok V. Krishnamoorthy et al., the contents of which are herein incorporated by reference.

### STATEMENT REGARDING FEDERALLY SPONSORED RESEARCH OR DEVELOPMENT

This invention was made with government support under Grant/Contract No. 1927082 awarded by the National Science Foundation. The government has certain rights in the invention.

### FIELD

The present disclosure relates to an optical source, such as a laser. More specifically, the present disclosure relates to a laser that outputs multiple lasing wavelengths without mode hopping.

### BACKGROUND

Optical frequency combs have found application in a wide variety of fields, such as: atomic clocks, precision frequency and wavelength measurement, LIDAR, tunable laser referencing, arbitrary waveform generation, and dense wavelength division multiplexed (WDM) optical communications. Moreover, there are many types of frequency comb generation techniques including: short-pulse mode-locking techniques, non-linear comb generation using high-Q resonators, frequency continuum combs using femtosecond pulsed lasers, electronic (RF) comb generation, semiconductor distributed feedback (DFB) laser, distributed Bragg reflector (DBR) laser arrays, heterogeneously integrated III-V/Si laser arrays, hybrid III-V/Si laser arrays, and multiple-wavelength quantum-dot lasers.

Existing comb lasers include: intra-optical (or laser) cavity phase-modulated comb lasers, mode locked comb lasers, parametrically amplified comb lasers (in micro-resonators and optical fibers), arrayed waveguide (AWG) lasers, and quantum-dot comb lasers. Typically, mode locked lasers (MLLs) have a frequency spacing defined by their optical cavity length and have been demonstrated on a bench top, in optical fiber with a graphene saturable absorber, and integrated in III-V or III-V/silicon. Moreover, in the case of a harmonically MLL, the comb spacing of MLLs can be modified to achieve a harmonic of the optical cavity, which makes a physically elegant comb source, but has shown limited power uniformity per line, and bandwidth because of optical cavity dispersion. Furthermore, through careful waveguide engineering, non-linear amplification can also create frequency combs, exemplified in micro-resonator combs. Note that many of the constraints of the MLLs have been solved with optical cavity-less parametric amplifier-based comb lasers. Optical cavity-less parametric amplifier-based comb lasers have been demonstrated with large bandwidths (greater than 100 nm), tunability, and considerable average power (greater than 22 dBm). However, the efficiency of optical pumping and the compactness of optical fiber-based lasers have not been shown to be viable in data centers. Additionally, proposals for using a scalable (e.g., a changing number of comb lines) and flexible (such as a dynamic diversity of channel spacing) grid have not been met with these lasers, which have usually had a fixed channel spacing with a bandwidth/channel count determined by the dispersion and/or filter selection of the high-index optical fiber used in parametric amplification process.

In contrast to the MLLs and optical fiber comb lasers, another example is a Vernier-ring comb laser in which each wavelength is addressable by its own gain section, so that uniform or tailored power balancing can be achieved. Similarly, the AWG laser may use multiple gain sections in parallel with the AWG acting as the wavelength multiplexing filter in the optical cavity and the multiplexer for a single comb output. AWG lasers have been demonstrated in indium phosphide and heterogeneous III-V/silicon. In these lasers, each gain section may be locked to the channel of its AWG arm and the grid spacing may also be fixed by the AWG. Because the AWG is typically not efficiently tunable, each gain section may address a specific channel and usually cannot act as spare for any other failed gain element (unless they incur the additional loss of a cyclic AWG design). Alternatively, ring filters are usually more compact and can be tuned per channel and tailored to achieve much narrower filtering to prevent mode-hopping, which is often a requirement for communications. Vernier ring lasers can also suppress side-modes (greater than 50 dB) and have shown narrow linewidths (less than 10 kHz), low relative intensity noise or RIN (less than −140 dB/Hz), and good efficiency, indicating that they are well suited for not only higher data rates, but also coherent communications. Note that an advantage of using silicon ring filters to multiplex the channels into a single optical waveguide is that the ring resonators can be realized in close proximity on the same silicon-on-insulator (SOI) die, which decreases the resonant wavelength misalignment of these two elements, thereby reducing transceiver tuning power.

Another candidate for a communications grade comb laser is the quantum-dot laser. Quantum-dot gain materials have been extensively investigated as a way to provide a multiple-wavelength laser without requiring mode-locked pulses or non-linear generation of wavelengths based at least in part on four-wave mixing in resonators. However, quantum-dot lasers are a unique type of multiple-wavelength laser, rather than solely as a unique gain medium. This is because, while quantum dots can replace quantum wells in many lasers, and often make excellent, stable, low RIN, MLLs, they typically have the unique characteristic of achieving multiple laser wavelengths in a Fabry-Perot (FP) optical cavity and even a DBR laser with enhanced temperature stability, without the uniformity, mode competition, and RIN issues that often occur in a traditional multiple-wavelength quantum-well FP laser. Notably, these capabilities occur because the carriers that populate a distribution of quantum dots are confined in the quantum dots without a statistically favorable transition between the quantum dots. Consequently, the result is that each wavelength can be supported by a unique population of quantum dots without significant competition, such that a single gain medium coupled to a comb reflector may lase with an array of wavelengths.

However, in practice, quantum-dot lasers are usually not suited for communications applications for several reasons. One challenge is the mode spacing. Notably, for many WDM systems, it is desirable to have lasing mode separation (or wavelength spacings) corresponding to several hundred GHz, and in some cases above 1 THz. Because the optical cavity size of quantum-dot FP lasers, the mode spacing is usually quite small (such as in the tens of GHz). Another challenge is the operational temperature range. Because laser wavelength red-shifts with temperature, it is usually impossible to provide sufficiently wavelength guard bands around each unique wavelength to accommodate temperature variations with quantum-dot FP lasers in the tens of degrees. With a small mode spacing, a third challenge is a large (and unpredictable) number of lasing modes are supported (such as 50-100), each with a relatively low optical power (often below 1 mW), which is split (often unevenly) between the various modes. The power in each mode is usually insufficient to support a communication link, and the overall RIN of a given mode as a result of mode beating or mode partition noise is typically less than is required for reliable communication. Moreover, a fourth challenge is that the stability of the modes is usually uncertain, with the likelihood of mode-hopping as the FP laser is subjected to electrical or optical noise and environmental fluctuations. Furthermore, a fifth challenge is that, with limited phase control and significant phase-noise, the linewidth of each lasing mode often broadens (to greater than 1 MHz), which can limit data communication distances and applications. While some of these issues have been addressed, a comprehensive solution to all of these issues with a tunable or flexible mode spacing has yet been achieved.

Thus, if a WDM source were available, ultra-efficient next generation multiple-wavelength transmitters may become possible with the capability to deliver orders of magnitude increases in bandwidth per optical fiber to the cloud per laser. Therefore, there is a need for improved comb laser sources.

### SUMMARY

In a first group of embodiments, an optical source is described. This optical source includes: an optical cavity that includes at least one mirror; and a semiconductor laser chip having multiple epitaxial gain layers, where the epitaxial gain layers act as a gain medium that provides multiple lasing wavelengths in a band of wavelengths without mode hopping and/or with significantly reduced mode beating below a predetermined value. Moreover, the optical source includes an optical component that selects laser modes of the optical cavity, where the optical component includes: an aperiodic grating; an echelle grating having a common arm that includes the epitaxial gain layers and multiple output arms that provide the lasing wavelengths; an optical de-interleaver having a common arm including the expitaxial gain layers and multiple output arms which provides the lasing wavelengths; or a set of ring resonators that provide the lasing wavelengths.

Note that the epitaxial gain layers may include layers with density of states with more engineered non-homogeneous broadening than intrinsic homogeneous broadening.

Moreover, the epitaxial gain layers may include InGaAs/GaAs self-assembled epitaxial gain layers.

Furthermore, the lasing wavelengths may be tunable.

Additionally, the optical source may include a distributed Bragg reflector (DBR) laser.

In some embodiments, the optical source may include a distributed feedback (DFB) laser.

Note that the semiconductor laser chip may include an optical waveguide and the aperiodic grating may be included in sidewalls of the optical waveguide. Alternatively, the semiconductor laser chip may include an optical waveguide and the aperiodic grating may be included above the optical waveguide.

Moreover, the mirror may include a distributed mirror.

Furthermore, the epitaxial gain layers may include quantum-dot gain layers or quantum-well gain layers.

Additionally, the epitaxial gain layers may be engineered to have inhomogenously broadened gain.

In some embodiments, the optical cavity may include an optical fiber.

Note that the optical source may include an absorber section, but may not use mode locking.

Moreover, the epitaxial gain layers may be configured to provide the multiple lasing wavelengths in the band of wavelengths with mode beating less than a predefined value. For example, the predefined value may be −120 dB/Hz (e.g., between −120 and −140 dB/Hz).

Furthermore, the multiple lasing wavelengths may include continuous lasing wavelengths.

Another embodiment provides an electronic device or a system that includes the optical source.

Another embodiment provides a method for providing lasing wavelengths, which may be performed by the optical source.

In a second group of embodiments, an optical source is described. This optical source includes: a semiconductor laser chip having: a gain medium in a first portion of an optical cavity that provides multiple lasing wavelengths in a band of wavelengths; and at least a first mirror. Moreover, the optical source includes a silicon-photonics chip optically coupled to the semiconductor laser chip, where the silicon-photonics chip provides a second portion of the optical cavity. The silicon-photonics chip includes: a first optical waveguide with a spot-size converter proximate to an interface between the semiconductor laser chip and the silicon-photonics chip; and a phase shifter that provides phase adjustment to an optical signal in the optical cavity. Furthermore, the optical source includes a micro-ring resonator optically coupled to the first optical waveguide and a second optical waveguide, where the micro-ring resonator provides resonant tuning of the optical source, and is an optical filter and a second mirror in the optical cavity. Additionally, the second optical waveguide conveys an output optical signal (which may be a portion of the optical signal) from the micro-ring resonator to an output port of the optical source.

Note that the semiconductor laser chip may include a III-V semiconductor. Moreover, the silicon-photonics chip may include silicon-on-insulator (SOI) or silicon nitride (SiN) on SOI.

Moreover, the output port may be optically coupled to a single-mode optical fiber.

Furthermore, the micro-ring resonator may have a free-spectral range (FSR) between 100 GHz and 800 GHz.

Additionally, a phase of the phase shifter may be adjusted using a first resistive heater or electro-optic tuning; and/or resonance frequencies of the micro-ring resonator may be adjusted using a second resistive heater or electro-optic tuning. Note that the resonance frequencies may be adjusted to match modes of the optical cavity.

In some embodiments, the optical source may include a tunable feedback element (such as a Mach-Zehnder interferometer or a directional coupler) optically coupling the first optical waveguide and the second optical waveguide.

Moreover, the optical source may include a second optical filter between the tunable feedback element and the micro-ring resonator, where the optical filter includes a Mach-Zehnder Interferometer (MZI), which may equalizes peak power at the lasing wavelengths.

Furthermore, the optical source may include a 1-to-N optical selector and an N-to-1 optical selector optically coupled to the first optical waveguide and the second optical waveguide. For example, the 1-to-N optical selector and/or the N-to-1 optical selector may be implemented using a tunable multi-mode interference coupler.

Additionally, the micro-ring resonator may perform resonant filtering and/or modulation of the optical signal. (Note that, for a stand-alone laser or u-Comb an un-doped ring resonator, which can provide filtering with low loss but not modulation, may be used.) In some embodiments, an optical demultiplexer may be optically coupled to the second optical waveguide. For example, the optical demultiplexer may include a set of micro-ring resonators that provide the lasing wavelengths. Alternatively, the optical demultiplexer may provide a set of parallel output ports that each provide a single lasing wavelength in the lasing wavelengths. Note that each of the output ports may include an optical modulator, where the optical modulator includes: a micro-ring modulator, a Mach-Zehnder modulator, and/or an electro-absorption modulator.

In some embodiments, the semiconductor laser chip may include a saturable absorber.

Note that the optical source may include a second micro-ring resonator and the micro-ring resonator and the second micro-ring resonator may provide a Vernier.

Moreover, the optical source may include: multiple instances of the semiconductor laser chip, located on a common or different substrates; the first optical waveguide; the spot-size converter; the phase shifter; and the micro-ring resonator. Each instance may correspond to different lasing wavelength in the lasing wavelengths. Furthermore, the optical source may include an output micro-ring resonator optically coupled to the second optical waveguide. Note that each of the instances of the semiconductor laser chip may have an associated quantum-dot (QD) gain correspond to one of the lasing wavelengths.

Additionally, the lasing wavelengths may be tunable, e.g., using the micro-ring resonator.

In some embodiments, the semiconductor laser chip may include a single-mode QD semiconductor laser chip.

Note that the micro-ring resonator may mode-lock lasing modes of the optical source by suppressing unwanted modes and re-enforcing lasing modes.

Moreover, by adjusting the phase of the phase shifter and the resonance frequencies of the micro-ring resonator, a center frequency of a passband of the micro-ring resonator may be matched to a non-zero integer multiple of a cavity-mode spacing.

Furthermore, the FSR may be tuned by switching between round-trip lengths of the optical signal in the optical cavity.

Another embodiment provides an electronic device or a system that includes the optical source.

Another embodiment provides a method for providing lasing wavelengths, which may be performed by the optical source.

This Summary is provided merely for purposes of illustrating some exemplary embodiments, so as to provide a basic understanding of some aspects of the subject matter described herein. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE FIGURES

FIG. 1 is a drawing illustrating an example of an optical source in accordance with an embodiment of the present disclosure.

FIG. 2 is a drawing illustrating an example of a side view of an integrated circuit in accordance with an embodiment of the present disclosure.

FIG. 3 is a drawing of an example the formation of a spectral gap in the gain spectrum and the appearance of multiple-frequency lasing in a quantum-dot laser with increasing driving current in accordance with an embodiment of the present disclosure.

FIG. 4 is a drawing of an example of a representation of a diode laser based at least in part on several planes of quantum dots in accordance with an embodiment of the present disclosure.

FIG. 5A is a drawing of an example of electroluminescence spectra at different drive current densities for a single array of InAs/InGaAs/GaAs quantum dots demonstrating the population of excited states with increasing pumping in accordance with an embodiment of the present disclosure.

FIG. 5B is a drawing of examples of a simplified ground-state (GS) and excited-state(ES) density of states for an array of self-assembled quantum dots grown under different growth conditions in accordance with an embodiment of the present disclosure.

FIG. 5C is a drawing of an example of a density of states of multiple layers of quantum-dots with different sizes and energy levels showing the density of states and the effective material gain in accordance with an embodiment of the present disclosure.

FIG. 5D is a drawing of an example of an idealized modal gain engineered by appropriate choice of quantum-dot layers and energies in accordance with an embodiment of the present disclosure.

FIG. 6A is a drawing of an example of a fixed periodic passband based at least in part on a sampled corrugated grating built on an optical waveguide using sidewall modulation in accordance with an embodiment of the present disclosure.

FIG. 6B is a drawing of an example of reflectivity of the structure with the desired periodic passband in accordance with an embodiment of the present disclosure.

FIG. 7 is a drawing of an example of an echelle grating wavelength demultiplexer in which input wavelengths on a common input optical waveguide are separated into corresponding output optical waveguides using a free-space, two-dimensional (2D) reflective diffraction grating in accordance with an embodiment of the present disclosure.

FIG. 8 is a drawing of an example of a cyclic demultiplexer or interleaver in accordance with an embodiment of the present disclosure.

FIG. 9A is a drawing of an example of a single-ring u-comb laser with a loop-mirror output in accordance with an embodiment of the present disclosure.

FIG. 9B is a drawing of an example of a single-ring u-comb laser with a directional coupler output in accordance with an embodiment of the present disclosure.

FIG. 10A is a drawing of an example of a dual-ring u-comb laser with light making two passes through the first ring per optical cavity round trip in accordance with an embodiment of the present disclosure.

FIG. 10B is a drawing of an example of a dual-ring u-comb laser with a directional coupler output in accordance with an embodiment of the present disclosure.

FIG. 10C is a drawing of an example of a filter passband for the dual-ring filter in accordance with an embodiment of the present disclosure.

FIG. 11A is a drawing of an example of an independent reflective semiconductor amplifier (RSOA) gain medium a directional coupler in accordance with an embodiment of the present disclosure.

FIG. 11B is a drawing of an example of an independent RSOA gain medium via a 2:1 splitter or switch in accordance with an embodiment of the present disclosure.

FIG. 12A is a drawing of an example of a type-2 u-comb in accordance with an embodiment of the present disclosure.

FIG. 12B is a drawing of an example of a type-3 u-comb in accordance with an embodiment of the present disclosure.

FIG. 13 is a flow diagram illustrating an example of a method for providing multiple lasing wavelengths using the optical source of FIG. 1 in accordance with an embodiment of the present disclosure.

FIG. 14 is a block diagram illustrating an example of a silicon-photonics external cavity laser in accordance with an embodiment of the present disclosure.

FIG. 15 is a drawing illustrating an example of continuous-wave output power versus current, power-conversion efficiency (PCE) of a silicon-photonics external cavity laser in accordance with an embodiment of the present disclosure.

FIG. 16 is a drawing illustrating an example of a spectrum of the silicon-photonics external cavity laser of FIG. 15 in accordance with an embodiment of the present disclosure.

FIG. 17 is a drawing illustrating an example of a tuning range of a silicon-photonics external cavity laser of FIG. 15 in accordance with an embodiment of the present disclosure.

FIG. 18 is a drawing illustrating an example of a tuning range of a silicon-photonics external cavity laser of FIG. 15 in accordance with an embodiment of the present disclosure.

FIG. 19 is a drawing illustrating an example of a laser with ring-filter resonances mis-aligned to cavity modes in accordance with an embodiment of the present disclosure.

FIG. 20 is a drawing illustrating an example of a laser with ring-filter resonances aligned to cavity modes in accordance with an embodiment of the present disclosure.

FIG. 21 is a block diagram illustrating an example of a multi-wavelength laser (MWL) with ring filter resonances aligned to cavity modes in accordance with an embodiment of the present disclosure.

FIG. 22 is a block diagram illustrating an example of a MWL implemented using an unbalanced Mach-Zehnder Interferometer (MZI) filter in accordance with an embodiment of the present disclosure.

FIG. 23 is a block diagram illustrating an example of tuning of a free-spectral range (FSR) during operation of a MWL in accordance with an embodiment of the present disclosure.

FIG. 24 is a block diagram illustrating an example of an implementation of a MWL in which the 1-to-N and N-to-1 selectors are implemented using tunable 1-to-N and N-to-1 multi-mode interference couplers in accordance with an embodiment of the present disclosure.

FIG. 25 is a block diagram illustrating an example of a MWL implemented using a tunable-length micro-ring in accordance with an embodiment of the present disclosure.

FIG. 26 is a block diagram illustrating an example of a transmitter with a MWL and cascaded ring resonators at the output in accordance with an embodiment of the present disclosure.

FIG. 27 is a block diagram illustrating an example of a MWL implemented using an optical demultiplexer that provides N optical outputs in accordance with an embodiment of the present disclosure.

FIG. 28 is a block diagram illustrating an example of a transmitter with a MWL implemented using an optical demultiplexer that provides N optical outputs in accordance with an embodiment of the present disclosure.

FIG. 29 is a block diagram illustrating an example of a MWL in accordance with an embodiment of the present disclosure.

FIG. 30 is a block diagram illustrating an example of a dual MWL in accordance with an embodiment of the present disclosure.

FIG. 31 is a block diagram illustrating an example of a Vernier MWL in accordance with an embodiment of the present disclosure.

FIG. 32 is a block diagram illustrating an example of a dual-gain Vernier MWL having a tunable spacing in accordance with an embodiment of the present disclosure.

FIG. 33 is a block diagram illustrating an example of a Vernier MWL with multiple RSOAs having a tunable spacing in accordance with an embodiment of the present disclosure.

FIG. 34 is a flow diagram illustrating an example of a method for providing multiple lasing wavelengths using an optical source in accordance with an embodiment of the present disclosure.

FIG. 35 is a block diagram illustrating an example of an electronic device that includes an optical source in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

In a first group of embodiments, an optical source is described. This optical source may include: an optical cavity that includes at least one mirror; and a semiconductor laser chip having multiple epitaxial gain layers, where the epitaxial gain layers act as a gain medium that provides multiple lasing wavelengths in a band of wavelengths without mode hopping and/or with significantly reduced mode beating below a predetermined value. Moreover, the optical source may include an optical component that selects laser modes of the optical cavity, where the optical component includes: an aperiodic grating; an echelle grating having a common arm that includes the epitaxial gain layers and multiple output arms that provide the lasing wavelengths; or a set of ring resonators that provide the lasing wavelengths.

By providing the multiple lasing wavelengths without mode hopping, these optical techniques may provide an efficient, tunable, flexible comb laser source with multiple-wavelength output channels (e.g., 4-64) and wide separation of wavelengths (such as 0.5-20 nm). Moreover, the output power, stability, and noise specifications of the optical source may exceed the requirements of communications lasers at 50 GBaud/s data rates per-wavelength output. Consequently, the optical techniques may address technical and cost bottlenecks associated with comb lasers in applications in a wide variety of fields, including: communications, health monitoring, spectroscopy, chemical identification, atomic clocks, precision frequency and wavelength measurement, LIDAR, tunable laser referencing, arbitrary waveform generation, and dense WDM optical communications.

In some embodiments, the optical techniques may provide a universal comb laser that combines an inhomogeneously broadened III-V quantum-dot gain medium embedded in laser cavity that contains a lossy, periodic reflector to create a semiconductor laser that lases in multiple lasing wavelengths that are dictated by the low-loss passbands of the periodic reflector. By suitable choice of the laser cavity design and reflector technology, the comb laser may have tunable spacings, a large number of wavelengths, and redundancy. The comb laser may use a variety of optical cavity designs, including multiple external optical cavity, integrated, and monolithic optical cavity designs, such as: optical fiber-Bragg-grating, free-space, monolithic III-V, and hybrid III-V/Si lasers. Aperiodic gratings may be integrated into the cavity to generate the lossy periodic reflector. Moreover, the quantum-dot comb laser may provide flexibility, efficiency, and redundancy that has not been achieved previously. Such a comb laser may be particularly useful in the context of micro-ring-mirror based silicon-assisted lasers. Note that ring-based filters and ring-based modulators use strong resonances respectively for filtering and modulation. Thus, these optical components can achieve high wavelength selectivity required for external optical cavity lasers and large extinction ratio for optical modulators.

In a second group of embodiments, an optical source is described. This optical source may include a semiconductor laser chip and a silicon-photonics chip that provide an optical cavity. The semiconductor laser chip may provide gain at multiple lasing wavelengths in a band of wavelengths. Moreover, the silicon-photonics chip may adjust a size of an optical signal proximate to an interface between the semiconductor laser chip and the silicon-photonics chip. Furthermore, by adjusting a phase of a phase shifter and resonance frequencies of a micro-ring resonator in the silicon-photonics chip, a center frequency of a passband of the micro-ring resonator may be matched to a non-zero integer multiple of a cavity-mode spacing. This may allow the optical source to mode-lock the lasing wavelengths of the optical source by suppressing unwanted lasing wavelengths and re-enforcing the lasing wavelengths. In some embodiments, a free-spectral range of the optical source may be between 100 GHz and 800 GHz.

By providing the multiple lasing wavelengths, these optical techniques may provide an efficient, tunable, flexible comb laser source with multiple-wavelength output channels (e.g., 4-64) and wide separation of wavelengths (such as 0.5-20 nm). Moreover, the output power, stability, and noise specifications of the optical source may exceed the requirements of communications lasers at 50 GBaud/s data rates per-wavelength output. Consequently, the optical techniques may address technical and cost bottlenecks associated with comb lasers in applications in a wide variety of fields, including: communications, health monitoring, spectroscopy, chemical identification, atomic clocks, precision frequency and wavelength measurement, LIDAR, tunable laser referencing, arbitrary waveform generation, and dense WDM optical communications.

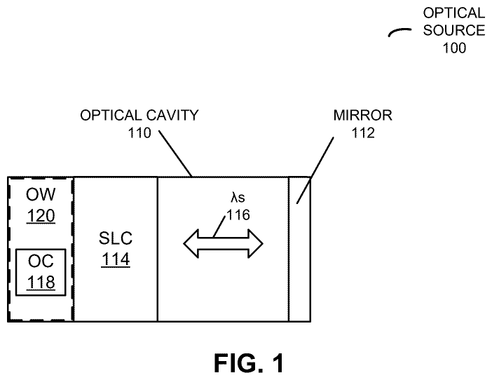

We now describe the optical techniques. FIG. 1 presents a drawing illustrating an example of an optical source 100. This optical source may include: an optical cavity 110 that includes at least one mirror 112; and a semiconductor laser chip (SLC) 114 having multiple epitaxial gain layers, where the epitaxial gain layers act as a gain medium that provides multiple lasing wavelengths (As) 116 in a band of wavelengths without mode hopping. Moreover, optical source 100 may include an optical component (OC) 118 that selects laser modes of the optical cavity. Note that optical component 118 may include: an aperiodic grating; an echelle grating having a common arm that includes the epitaxial gain layers and multiple output arms that provide the lasing wavelengths; and/or a set of ring resonators (e.g., one or more ring resonators) that provide the lasing wavelengths.

Note that the epitaxial gain layers may include layers with density of states with more non-homogeneous broadening than homogeneous broadening. Moreover, the epitaxial gain layers may include InGaAs/GaAs self-assembled epitaxial gain layers. Furthermore, the epitaxial gain layers may include quantum-dot gain layers or quantum-well gain layers. Additionally, the epitaxial gain layers may have inhomogenously broadened gain. In some embodiments, the epitaxial gain layers may be configured to provide the multiple lasing wavelengths in the band of wavelengths with mode beating and relative intensity noise (RIN) less than predefined values. For example, the predefined value for mode beating may be less than 100 kHz and the predefined value may be −130 dB/Hz (e.g., between −130 and −150 dB/Hz).

Moreover, optical source 100 may include a DBR laser. Furthermore, optical source 100 may include a DFB laser. Note that optical source 100 may not use mode locking.

Additionally, lasing wavelengths 116 may be tunable. In some embodiments, multiple lasing wavelengths 116 may include continuous lasing wavelengths.

Note that semiconductor laser chip 114 may include an optical waveguide (OW) 120 and the aperiodic grating may be included in sidewalls of optical waveguide 120. Alternatively, semiconductor laser chip 114 may include optical waveguide 120 and the aperiodic grating may be included above optical waveguide 120.

Moreover, mirror 112 may include a distributed mirror.

Furthermore, optical cavity 110 may include an optical fiber.

Some or all of optical source 100 may be implemented using a variety of fabrication platform. Note that there two classes of fabrication platforms: a CMOS platform (such as silicon-on-insulator) that can support homogenous integration with electronics; and other platforms, some of which have low-loss (such as silicon nitride, glass, etc.), that do not support homogenous integration.

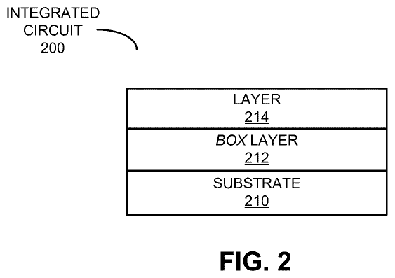

Thus, some or all of optical source 100 may be implemented on one or more integrated circuits. This is shown in FIG. 2, which presents a block diagram illustrating an example of a side view of an integrated circuit 200. This integrated circuit may include a substrate 210 and a buried-oxide (BOX) layer 212 disposed on substrate 210. Moreover, layer 214 may include a semiconductor layer disposed on BOX layer 212. This semiconductor layer may, at least in part, include optical waveguide 120 (FIG. 1). Thus, substrate 210 may include silicon, BOX layer 212 may include silicon dioxide and the semiconductor layer may include silicon. In some embodiments, there may be an oxide layer on top of layer 214.

However, as discussed previously, a wide variety of materials may be used to implement integrated circuit 200, including: SOI, a semiconductor (e.g., indium phosphide, aluminum gallium arsenide, aluminum gallium nitride arsenide, aluminum gallium arsenide phosphide, a III-V compound semiconductor, etc.), and/or an insulator optical waveguide (e.g., silicon dioxide or silicon nitride). Alternatively or additionally, integrated circuit 200 may include an electro-optic waveguide made from materials including: lithium niobate, thin-film lithium niobate (TFLN), barium titanate, and/or an organic material (such as an electro-optic polymer). For example, integrated circuit 200 may include a substrate that is an insulator. Consequently, layer 214 may include: silicon, silicon dioxide, and/or silicon nitride. Therefore, integrated circuit 200 may be implemented using a variety of integrated optical waveguide technologies.

In some embodiments, lasing wavelengths 116 may be between 1260-1360 nm or 1500-1600 nm. For example, lasing wavelength 116 may be between 1.1-1.7 μm, such as 1.3 or 1.55 μm. Moreover, layer 214 may have a thickness that is, e.g., less than 1 μm (such as 0.2-0.5 μm). For example, layer 214 may have a thickness, e.g., of 0.3 μm. Additionally, BOX layer 212 may have a thickness, e.g., between 0.3 and 3 μm (such as 0.8 μm).

Note that optical waveguide 120 (FIG. 1) may include a ridge optical waveguide or a channel optical waveguide. Moreover, optical waveguide 120 (FIG. 1) may be a single-mode optical waveguide. For example, optical waveguide 120 (FIG. 1) may have a width of 500 nm.

The preceding embodiments may include additional or fewer components. Moreover, positions of one or more components may be changed, two or more components may be combined into a single component and/or a component may be divided into two or more components.

The disclosed optical techniques provide an efficient (single-gain medium), tunable (by design or in-situ), flexible (in terms of the number of wavelengths and mode-spacing) semiconductor quantum-dot comb laser source with multiple, predictable wavelength output channels (e.g., four to more than 64) with specifications per-wavelength output. This comb laser may exceed the requirements of communications lasers at 50 GBaud/s data rates and higher.

In some embodiments, a semiconductor quantum-dot FP laser using the optical techniques may support multiple longitudinal optical cavity modes with a well-defined spacing based at least in part on a length of the FP optical cavity. At low temperatures, quantum dots with different energies begin lasing independently because they have no correlation to each other and, thus, independently provide optical gain to different lasing modes supported by the FP optical cavity. As the temperature is increased, homogeneous broadening increases the gain available to a lasing mode of a given energy (or wavelength) by collecting the contributions of the quantum dots, regardless of spatial location, within the homogeneous broadening of that specific energy. Multiple wavelengths can lase simultaneously when the homogeneous broadening is limited and when a large population of inhomogeneously broadened quantum dots exist within the laser cavity. Note that room temperature operation of a large number of such FP modes has been demonstrated. A special case may occur when homogeneous broadening of the quantum-dot optical gain medium is comparable to its inhomogeneous broadening. Therefore, in some embodiments, the lasing spectrum may adapt to support only a few (or even a single) longitudinal optical cavity mode.

The optical materials engineering techniques (such as appropriate cavity design and/or optical circuit techniques, and which are distinct from the QD materials techniques that are used during the growth of the QD materials) may significantly increase the inhomogeneous broadening of the quantum-dot gain material to far exceed the homogeneous broadening of the quantum dots. This can be done over a very wide bandwidth of, e.g., up to 15 THz (85 nm). Moreover, the optical circuit techniques may introduce an engineered loss-band into the optical cavity to suppress unwanted lasing modes that may be supported by the laser cavity. This capability may provide multiple benefits: it may prevent power being emitted into unwanted modes that may otherwise lase with support by the inhomogeneously broadened quantum-dot gain′ and it may reduce the possibility of undesired mode hopping between closely spaced laser cavity modes within a homogeneously broadened distribution of quantum dots. Furthermore, the optical circuit techniques may create an engineered optical cavity passband that provides very low-loss at desired locations with the inhomogeneously broadened optical cavity gain spectrum. If the passband provides a single, adjustable low-loss optical cavity resonance, a tunable laser may be obtained. When this passband is engineered to have a high-finesse periodic nature with a free-spectral range (FSR) greater than the homogeneous broadening of the quantum-dot gain material and a resonance linewidth (e.g., as measured by its full-width half-max) lower than the homogeneous broadening of the quantum-dot material, an engineered comb laser or u-comb laser may be obtained.

Multiple types of u-comb lasers may be achieved using the optical techniques. Note that a type-1 quantum-dot u-comb may be one with a pre-specified wavelength spacing and pre-specified lasing wavelengths (such as fixed passband locations). Furthermore, type-2 u-combs may include limited tuning of the comb center wavelength through phase tuners or thermal tuners that can simultaneously shift all the wavelengths. but that do not significantly alter the comb spacing. Note that some embodiments of type 1 or type 2 u-combs may allow for equalization of power between the lasing wavelengths, but may not enable the spacing of the wavelengths to be altered. For full flexibility, a type-3 u-comb may provide the user with adjustments for individual wavelengths of the comb, thereby allowing both the center wavelength and the wavelength spacing to be tuned by the user. For all three comb types, redundancy may be provided by using a spare quantum-dot gain element.

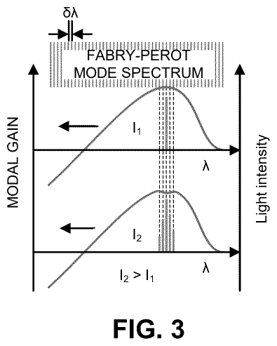

The disclosed optical techniques may be used in multiple embodiments of the quantum-dot u-combs. For type-1 u-combs, the comb laser may include: a free-space external optical cavity configuration, a set of optical fiber-Bragg-gratings in an optical fiber-based external optical cavity laser; a silicon, SiO₂, SiON, SiN, lithium niobate, thin-film lithium niobate, barium titanate, an electro-optic polymer and/or a polymer organic photonic integrated circuit component to create the external optical cavity, or a periodic-passband grating or optical filter monolithically integrated with the laser (e.g. a DFB comb). When the passband is fixed, such as with a passive optical fiber-Bragg grating, a free-space periodic reflector, an Echelle grating or an AWG in a silcon/SiO₂/SiON/SiN structure, a single micro-ring filter and/or a set of micro-ring filters (such as a Vernier pair), then a type 1 u-comb may be achieved. This is illustrated in FIG. 3, which presents a drawing of an example of the formation of a spectral gap in the gain spectrum and the appearance of multiple-frequency lasing in a quantum-dot laser with an FP optical cavity with increasing driving current.

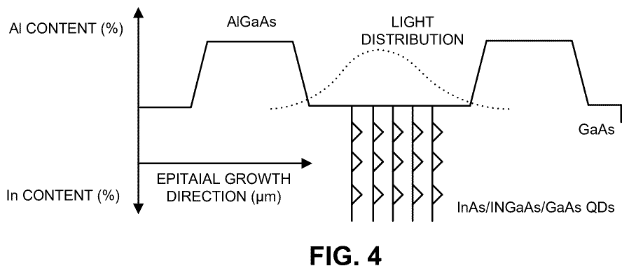

Assuming there is a mechanism to thermally or electrically (e.g., via the electro-optic or thermo-optic effects) move the periodic passband so that it is incorporated into the passive filter, then a type-2 u-comb laser cavity may be achieved. For example, this capability may be achieved with a compact ring-resonator structure that provides the periodic passband by suitable choice of Q-factor and FSR of the ring filter. This is illustrated in FIG. 4, which presents a drawing of an example of a representation of a diode laser based at least in part on several planes of quantum dots. In addition, a type 2 comb may include means for equalizing the power in different wavelengths.

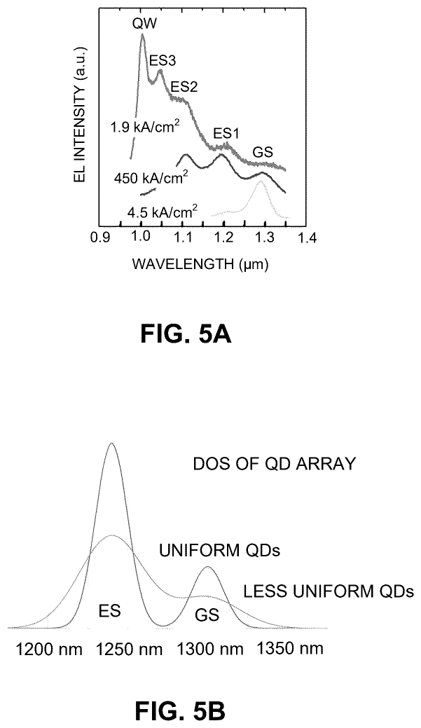

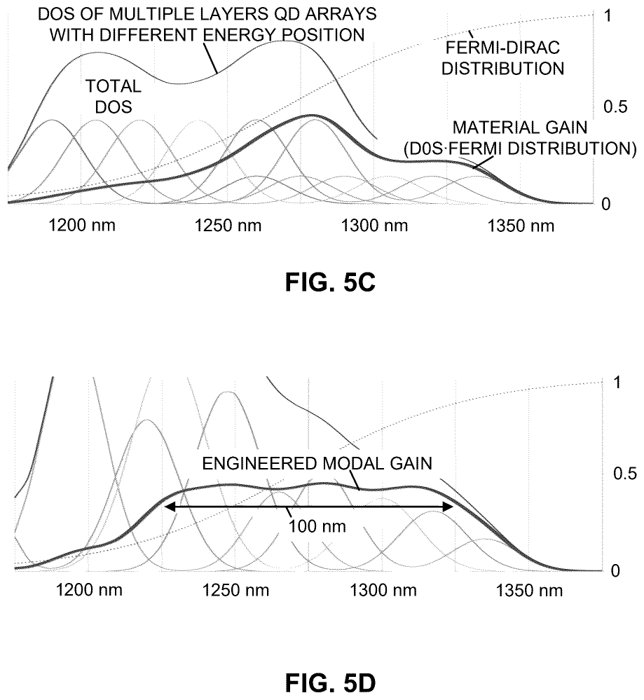

In order to provide selectivity of the wavelengths and the spacing, and/or normalize power across wavelengths, an implementation of a type-3 u-comb may include the use of a common ring to define the common denominator wavelength separation and a set of individual rings to select/enable specific lasing wavelengths at multiples of the common wavelength separation. Phase tuning elements may additionally be include adjacent to the individual rings to enable fine tuning and/or normalization of loss across the wavelengths. The engineered gain spectra are is shown in FIGS. 5A-5D. Notably, FIG. 5A presents a drawing of an example of electroluminescence spectra at different drive current densities for a single array of InAs/InGaAs/GaAs quantum dots demonstrating the population of excited states with increasing pumping; FIG. 5B presents a drawing of examples of a simplified GS and ES density of states for an array of self-assembled quantum dots grown under different growth conditions; FIG. 5C presents a drawing of an example of a density of states of multiple layers of quantum-dots with different sizes and energy levels showing the density of states and the effective material gain; and FIG. 5D presents a drawing of an example of an idealized modal gain engineered by appropriate choice of quantum-dot layers and energies. This capability may provide the ability to have non-uniform spacings, but a predictable multiple of the common wavelength spacing. Other embodiments of type-3 u-combs may provide flexibility of choice in terms of the passband. Note that the embodiments may balance the complexity and loss of the filter passband with the desired tunability and flexibility required by the application. The output of the u-comb may be obtained at the near-end of the quantum-dot gain element and/or at the far-end of the passive filter. In the former embodiments, a quantum-dot semiconductor-optical-amplifier may be monolithically integrated next to the quantum-dot gain section of the u-comb for power-boosting the emitted wavelengths as they exit the laser.

Fundamentally, the broader lasing spectrum of an FP laser based at least in part on quantum dots compared to its quantum-well counterpart may be the enhanced spectral hole-burning effect caused by the finite carrier capture time for lasing and the much lower maximum density of states. Consequently, once the drive current exceeds the lasing threshold current, the Fermi level may not be pinned once the lasing starts. Multiple FP lasing lines may achieve the lasing condition, namely that total loss equals to modal gain. This effect is shown in FIG. 3, which depicts the case for a quantum-dot FP laser with multiple lasing lines with a separation determined by the optical cavity length.

Note the effect of spectral hole burning in quantum-dot lasers may be sufficiently pronounced that lasing even can be achieved on ground states (GS) and first excited states(ES) simultaneously. However, in order to build a u-comb laser with good power conversion efficiency and uniform performance of each lasing mode, the overall modal gain of quantum dots may need to be to properly designed and/or engineered.

The modal gain (g_{mod}) of a diode laser is proportional to material gain (gₘₐₜₑᵣᵢₐₗ) multiplied by the overlap of electron and hole wavefunctions with a light distribution (Gamma factor):

g_{mod}(E)˜Γ·gₘₐₜₑᵣᵢₐₗ(E).

Noted that both gain curves may be photon-energy dependent and, thus, wavelength dependent.

As shown in FIG. 4, typical GaAs quantum-dot lasers contain between three and 15 layers of self-assembled quantum dots placed in the GaAs optical waveguide and sandwiched by AlGaAs cladding layers.

Moreover, the material gain may be proportional to the combined density of states of electron and holes (D(E)) in quantum dots multiplied by the Fermi-Dirac distribution (F(E,T)), which is a function of temperature and the Fermi level position:

gₘₐₜₑᵣᵢₐₗ(E)˜D(E)·F(E,T).

In order to achieve intensity and slope efficiency (mW/mA) uniformity of each lasing lane in a u-comb laser, the modal gain at drive current close to threshold current may be designed to be more or less flat through the entire range of desired lasing wavelengths. The quantum-dot modal gain may be engineered by selecting a quantum-dot size distribution, which directly affects D (E). Additional flexibility may be given by a non-uniform Gamma factor for quantum-dot layers placed in different positions in the optical waveguide (as shown in FIG. 4).

Furthermore, another issue to be taken into account when designing an epitaxial structure for u-comb laser is that quantum dots emitting in O-band have several excited states with a certain degeneracy, which has been theoretically shown and experimentally proven. FIG. 5A shows the electroluminescence under high drive-current pumping, where the energy of several states (cumulated electron and hole) of quantum-dot arrays can be resolved. Note that because of the Fermi distribution at lower current densities, the higher energy states have lower luminescence in spite of a higher D (E).

Under reasonable current densities, the GS and the first ES contribute to population inversion and, therefore, to lasing conditions of typical O-band quantum-dot lasers. The shape of the GS material gain of a single quantum-dot array is close to a Gaussian distribution. Moreover, the width of this distribution height may be varied by growth conditions during epitaxial deposition of thin InAs layers on GaAs, as well as by the quantum-dot design, e.g., InAs quantum dots covered by InGaAs quantum well(s). FIG. 5B shows examples with a continuous (uniform) density of states, as well as discretized (less uniform) variants.

Furthermore, FIGS. 5C and 5D show the modal gain versus wavelength of the laser based at least in part on several layers of quantum dots having the same Gamma factor at certain Fermi level values. Note that FIG. 5B shows an example of how the aforementioned optical techniques may be applied to form a uniform modal gain over the whole O-band.

In the discussion that follows, we describe embodiments of the three types of u-comb lasers based at least in part on such engineered quantum-dot gain chips that can be implemented using a variety of technology platforms.

Type 1 u-Comb Lasers

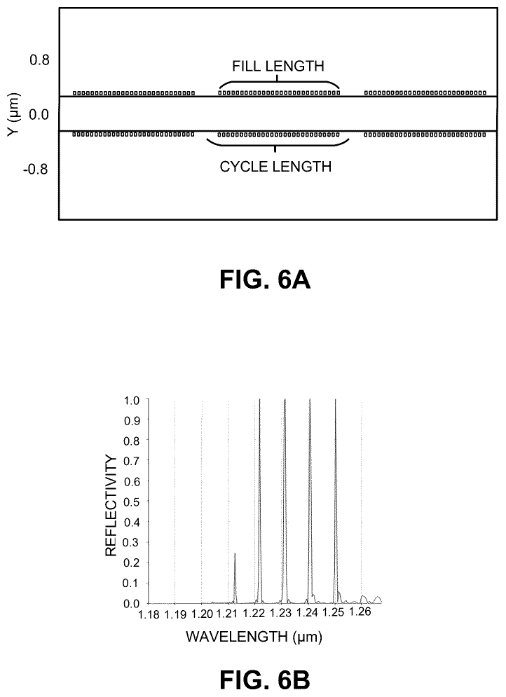

We first begin with a discussion of the filter requirements for a u-comb filter that is designed to have a periodic low-loss passband with high-loss (stop-band) everywhere else. This can be obtained by multiplying a grating (single Fourier frequency) by an aperture function to create a sampled grating. Using appropriate design of the sampled grating, we can create the necessary spacing between the passbands. Furthermore, the grating may be apodized to create a single low-loss passband with a small full-width at half maximum. The overall reflectivity of the component represents a high-finesse optical cavity with multiple low-loss peaks. FIG. 6A presents a drawing of an example of a corrugated grating that creates the desired periodic passband. In this embodiment, there are two parameters: a fill-length, and a cycle-length. These respectively correspond to the grating fill width and the cycle width that includes a section of no gratings or perturbations to the optical waveguide. Additionally, the grating may be apodized by varying the grating period along its length in each cycle. Note that the apodized grating may be multiplied by a periodic square-wave defect. In some embodiments, the grating may be present within the ‘fill length’ across the period of ‘cycle length.’

Based at least in part on the desired reflectivity spectrum, it is possible to design a grating with varying spacing (e.g., up to 10 nm) using this technique. It is also possible to model and optimize the grating apodization capabilities when the etch-depth is proportional to the grating opening, which is sometimes the case with III-V material etching. Note that local defects in the gratings may introduce loss, but may not affect the overall position of the reflective passband peaks (or equivalently the lasing modes) when the number of cycles used is large.

Moreover, the reflectivity passband may then be combined with a quantum-dot material with large, controlled inhomogeneous broadening. Depending on material and growth conditions, homogeneous broadening of semiconductor quantum-dot gain chips may limited to in the range of 1-3 nm (and possibly higher). Consequently, the FSR of the reflectivity peaks may be chosen to be greater than this value. Furthermore, the overall number of lasing wavelengths of the resulting u-comb laser may be determined by the extent of the inhomogeneous broadening and the number of low-loss peaks in the reflectivity spectrum. This is shown in FIG. 6B, which presents a drawing of an example of the reflectivity of a structure with the desired periodic passband. In this embodiment, four low-loss peaks are created with 100 cycles.

Additionally, a single-mode (single-wavelength) DFB laser may be created by monolithically integrating a distributed-feedback reflective grating into a III-V semiconductor laser. In order to create a type 1 u-comb laser, such a grating may be monolithically implemented in a III-V quantum-dot wafer process. This multiple-wavelength laser may be referred to as a DFB-comb laser.

In some embodiments, other widely known technology platforms may be used to create type 1 u-combs. For example, a DBR may be constructed in short segments of optical fibers by creating periodic variations in the refractive index of refraction of the optical fiber core. This may result in an in-line optical fiber reflector. Consequently, a quantum-dot gain stripe with a high-reflectivity coating and an anti-reflection coating, which together create a quantum-dot reflective semiconductor amplifier (RSOA), may be combined with a sampled optical fiber Bragg grating (as described previously) generated in a single-mode optical fiber to create a type 1 u-comb with a naturally optical fiber-coupled output. This embodiment may be referred to as an SFBG-comb laser.

Another embodiment of a type 1 u-comb may use an external optical cavity laser configuration based at least in part on a SiO₂ (silica), SiN or SOI that includes a wavelength demultiplexer and wavelength-selective mirrors to create a high-finesse periodic reflector.

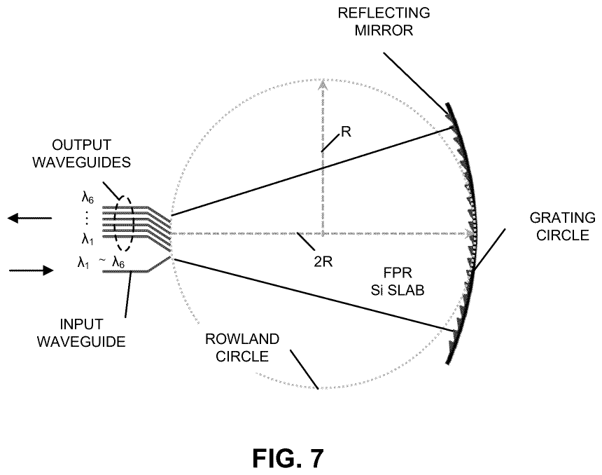

FIG. 7 presents a drawing of an example of an echelle grating wavelength demultiplexer in which input wavelengths on a common input optical waveguide are separated into corresponding output optical waveguides using a free-space, two-dimensional reflective diffraction grating. Notably, in FIG. 7, an echelle grating may have one input optical waveguide and multiple output optical waveguides (e.g., the six shown in FIG. 7) that filter out different wavelength channels coming from the input optical waveguide. In some embodiments, the echelle gating may be modified to include a quantum-dot gain material connected to the common optical waveguide with a DBR or HR mirrors to complete an optical cavity. Note that a wavelength-tuned DBR mirror or a broadband HR mirror may be included in each of the output optical waveguides. Moreover, an optional a phase-tuning section may be included one of the output optical waveguides. Furthermore, an active gain medium may be integrated with a second partially reflecting wideband mirror at the input optical waveguide (which may also be DBR mirror). In some embodiments, multiple physically separate lasing cavities may be simultaneously established with the quantum-dot gain material. Note that each optical cavity may include the common partially reflective DBR mirror, a common echelle grating section (which further separates the wavelengths 21 to 26 into corresponding separate output optical waveguides), and a separate DBR mirror or HR mirror associated with each of the separate optical waveguides. Thus, in some embodiments of FIG. 7, reflective echelle gratings may be combined with quantum-dot gain components placed in the common optical waveguide to create an echelle-comb laser with a fixed channel spacing. Moreover, echelle-comb laser outputs may be available on a common optical waveguide. Furthermore, reflective echelle gratings may be flexibly designed to produce a passband with a large number of wavelengths and high rejection of unwanted wavelengths.

Note that this may form a type 1 u-comb laser that additionally is tolerant to manufacturing variations and is stable to environmental variations. Furthermore, the different wavelengths may propagate through the same two-dimensional slab region, may share the same diffraction gratings, and thus may experience the same manufacturing and ambient variations. Consequently, the spacing deviation between two adjacent channels may be small.

As discussed previously, in FIG. 7 a broadband quantum-dot semiconductor-optical-amplifier (SOA) may be monolithically integrated adjacent to the quantum-dot gain section (and outside the optical cavity of the u-comb laser). This configuration may power boost the emitted wavelengths as they exit the laser.

Another potential embodiment of a type 1 u-comb may be to use an arrayed waveguide grating router (AWGR)-based demultiplexer with partial, wavelength-selective mirrors or HR mirrors to create an AWGR-comb.

In general, there may be multiple ways to integrate the quantum-dot gain components with the SOI, SiN, SiO₂ or another optical platform. This may include chip-to-chip edge coupling, chip-to-chip surface-normal coupling, evanescent coupling to the III-V quantum-dot gain material though heterogeneous integration of the quantum-dot gain material onto the host SOI, SiN, SiO₂ or other optical platform, and/or another technique of hybrid integration (such as chip-to-chip edge coupling, chip-to-chip surface-normal coupling, and/or photonic wire-bonding).

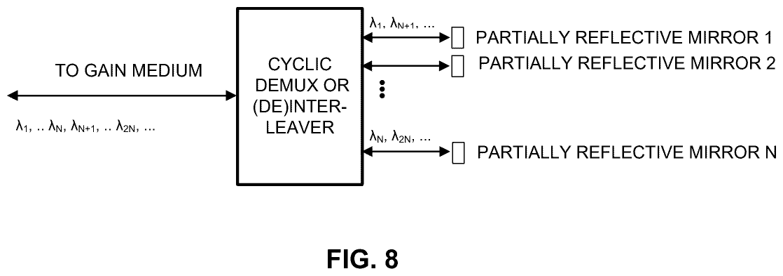

Other Cavity Filter Structures May be Anticipated. For Example, Passive De-interleavers with Bragg mirrors or ring-based mirrors may be used at the end of each de-interleaved path to create the desired filtered reflection spectra for the requisite lasing wavelengths. These mirrors may further be partially reflecting to create an array of output ports for the comb, with each output containing a selected subset of comb wavelengths. FIG. 8 presents a drawing of an example of a cyclic demultiplexer or interleaver.
Type-2 u-Comb Lasers

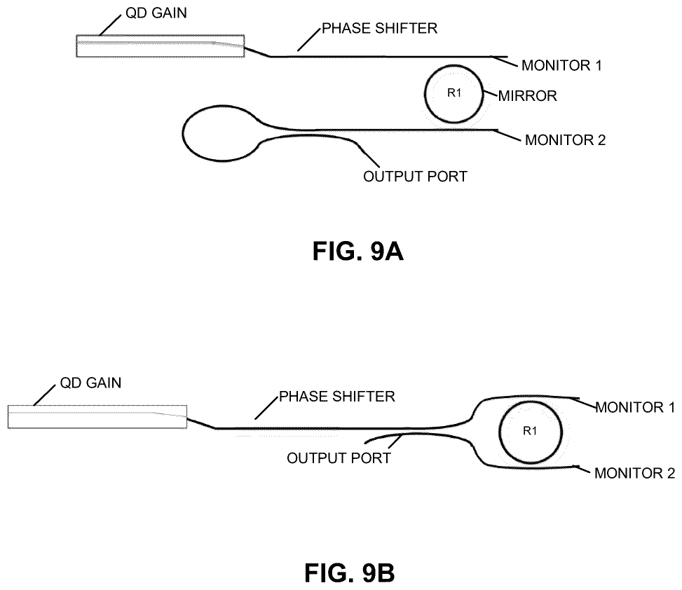

A type-2 u-comb may enable electrical tuning of the comb center wavelength through phase tuners or thermal tuners, which may simultaneously shift all the wavelengths. Two basic designs of a type-2 c-comb laser using ring filters are shown in FIGS. 9A and 9B. Notably, in FIG. 9A, which presents a drawing of an example of a single-ring u-comb laser with a loop-mirror output, a loop mirror after the ring may be used to define an output port. Note that an optical cavity round-trip may include two passes through the ring R1. Moreover, in FIG. 9B, which presents a drawing of an example of a single-ring u-comb laser with a directional coupler output, a directional coupler before the ring may be used to define the output port. In this embodiment, an optical cavity round-trip may include one pass through the ring R1 with two degenerate modes (clockwise and anti-clockwise propagating ring modes). Note that in FIG. 9B, the total round trip cavity length can be minimized versus that in FIG. 9A, because only one pass is made through the resonant ring filter. This reduced cavity length increases the intrinsic cavity mode spacing, which permits improved selectivity with higher relative side-mode suppression of the unwanted cavity modes for a given ring resonator quality factor. Consequently, FIG. 9B may provide favorable performance benefits in terms of u-comb stability and mode-hop-free behavior. In the embodiments shown in FIGS. 9A and 9B, the ring may be tuned thermally and/or electro-optically to adjust the center wavelengths of the comb. However, the wavelength spacing may be fixed by the FSR of the ring filter. Additionally, in the embodiments in FIGS. 9A and 9B, there may be monitor ports that are used to align the ring mirror (R1) with the optical cavity mode by minimizing power at the monitor photodetector (PD) ports.

Type-3 u-Comb Lasers

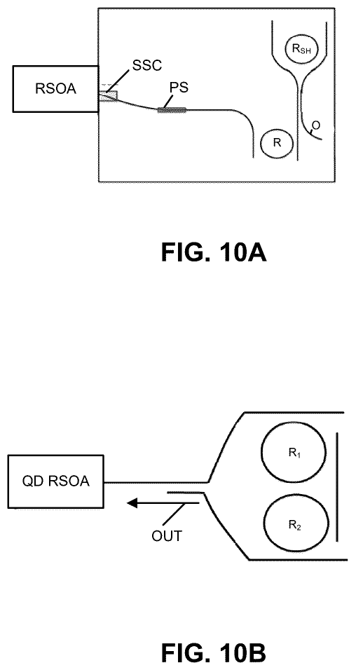

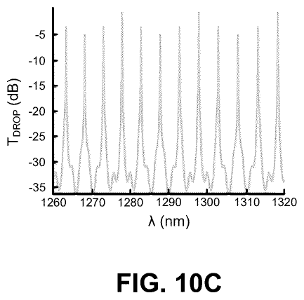

A type-3 u-comb may provide the user with adjustments of individual comb wavelengths, thereby allowing both the center wavelength and the wavelength spacing to be tuned by the user. FIGS. 10A and 10B show two basic designs of a type-3 u-comb laser using dual-ring filters with different radii rings to create a Vernier filter. In the embodiment shown in FIG. 10A, which presents a drawing of an example of a dual-ring u-comb laser with light making two passes through the first ring per optical cavity round trip, a spot size converter (SSC) may be optionally used to convert the profile of the optical waveguide mode and a phase shifter (PS) may be included to align the optical cavity mode to the dual-ring filter. Moreover, the optical cavity may include a directional coupler output after the second ring. Note that each ring may be tuned thermally and/or electro-optically to adjust the center wavelength and the spacing of the wavelength comb. Depending on the choice of the ring radii and their relative difference, a wide range of comb spacings may be achieved. Furthermore, in FIG. 10A, a loop mirror after the first ring may be used to define the output port. Note that an optical cavity round-trip may include two passes through the ring R1 and one pass through Rₛₕ with two degenerate modes (clockwise and counterclockwise propagation).

Furthermore, in FIG. 10B, which presents a drawing of an example of a dual-ring u-comb laser with a directional coupler output, the directional coupler before the pair of rings may be used to define the output port. In this embodiment, an optical cavity round-trip may include one pass through each of ring R1 and ring R2 with two degenerate modes (clockwise and anti-clockwise propagating ring modes). SSC and PS (not shown) may be optionally included in FIG. 10B. Additionally, in FIGS. 10A and 10B, feedback monitor ports (not shown) may be used to align the ring-mirror mirrors (R, Rₛₕ and R1, R2) in FIGS. 10A and 10B with their respective optical cavity modes. FIG. 10C presents a drawing of an example of a filter passband or response for the dual-ring filter for the laser cavity.

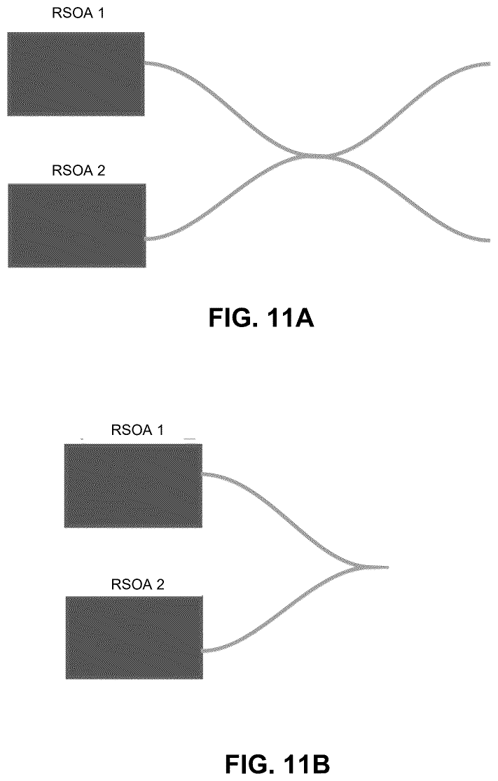

As shown in FIGS. 11A and 11B, redundancy may be provided by using a spare quantum-dot gain element as a second independent RSOA gain medium in types 1, 2, and 3 u-comb. Notably, FIG. 11A presents a drawing of an example of an independent RSOA gain medium via a directional coupler. Note that reciprocity may guarantee that all light originating from a given RSOA or gain section may return to that section to complete the laser cavity. Moreover, FIG. 11B presents a drawing of an example of an independent RSOA gain medium via a 2:1 splitter or switch.

A further extension to the use of two RSOAs in an independent lasing condition may be achieved by using of a directional coupler with a 50% power-splitting ratio. This may allow a comb laser to use a second quantum-dot RSOA at the input as a second independent quantum-dot amplifier, which may be switched on with off and/or may simultaneously lase and may be modulated with the same external optical cavity without gain competition. This design may provide multiple benefits. For example, RSOA 1 may be switched off and RSOA 2 may be switched on to permit the external optical cavity to lase and may be modulated at a completely different wavelength range (e.g., to extend the range of the u-comb). In another mode of operation, a constant current may be applied to RSOA 1 to create a stable u-comb. Simultaneously, RSOA 2 may be amplitude modulated via carrier injection to create a comb with a carrier modulation frequency. This second lasing comb may also have the superimposed modulation and may be interleaved with the first comb. At the output, the frequency-modulated comb information associated with the RSOA2 lasing wavelength comb may be filtered and discriminated from the RSOA 1 comb, while wavelength filtering may be used to separate the lasing modes of each comb. This approach may also permit a secondary wavelength comb to carry lower bandwidth data at a separate set of wavelengths, which may be useful for certain system applications.

While the preceding discussion has focused on the use of RSOAs with the comb output from the far side of the optical cavity, note that that the quantum-dot gain medium or chip may be integrated monolithically on the same wafer or hybrid/heterogeneously integrated with an optical cavity created on a different Si, SiN, SiO₂, LNOI (lithium niobate on insulator) or other wafer. Depending on how the integration is achieved, it may be advantageous to place the quantum-dot gain in the interior of the laser cavity or to have the comb output at the near-end of the quantum-dot gain medium.

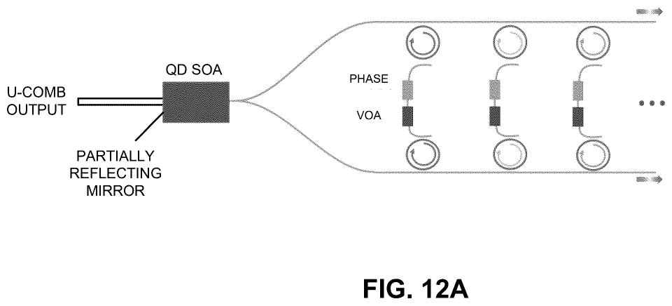

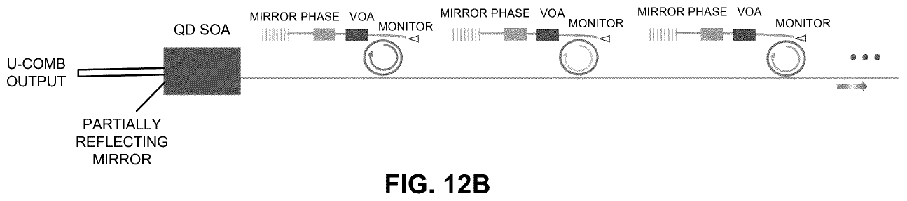

FIG. 12A presents a drawing of an example of a type-2 u-comb, and FIG. 12B presents a drawing of an example of a type-3 u-comb. Notably, FIGS. 12A and 12B depict modifications of the type-2 and type-3 u-combs with a cascaded series of single-ring and dual-ring filter cavities respectively sharing the common quantum-dot gain medium. In these embodiments, the comb-laser output may be from the partially reflecting mirror at the quantum-dot gain chip, which may be implemented using gratings or coatings. Moreover, the external optical cavity may perform the function of a back-side mirror. This arrangement may provide multiple optical cavities, each with a single-ring or dual-ring-modulator pair that may be tuned to control the lasing wavelengths and comb spacing. As discussed earlier, a given optical cavity may be integrated with the gain medium through a number of techniques, including: wafer bonding, transfer printing, epi-growth, and/or hybrid integration. In some embodiments, an optional quantum-dot booster SOA may be integrated outside the laser cavity (e.g., close to the quantum-dot gain section) to boost the output power from the comb.

Thus, in FIG. 12A, light in a type-2 u-comb may make two passes through the first ring per optical cavity round trip and exit through a partially reflective mirror at the quantum-dot SOA near-end optical cavity mirror. A high-reflectivity mirror provided on the far side of the ring (which can also be partially leaky) may enable a power-monitoring photodetector (not shown) to detect output power once calibrated. In some embodiments, as shown, it may be useful to have another optical cavity ring (a second ring-comb optical cavity). This may enable a separate interleaved comb if desired and may provide a technique for achieving a type 3 u-comb with an adjustable wavelength spacing. Moreover, as shown, a phase tuner may be included to align the optical cavity modes to the ring filter peaks, and a variable optical attenuator (VOA) may be added to equalize power between ring reflectors. Alternatively, in FIG. 12B, each dual-ring pair in a type 3 u-comb with a splitter before the first ring has a bus optical waveguide to complete the optical cavity. Moreover, a phase shifter may be included to align the optical cavity mode to the dual-ring filter. Furthermore, a second pair of rings may provide an independently adjustable dual-ring Vernier filter. VOAs may be included in the bus optical waveguide of each pair to equalize power. Note that an optical cavity round trip may include a single pass through both rings with degenerate modes traveling clockwise and anti-clockwise through each pair of rings. The comb laser output may be at the quantum-dot SOA partially reflective mirror. In FIGS. 12A and 12B, feedback monitor ports (not shown) may be used to align the ring mirror mirrors.

Moreover, in some embodiments, a number of ring coupling conditions may be possible. In one arrangement, a ring modulator may be symmetrically coupled to its corresponding output port buses and shared drop buses. Alternatively, rings may be critically coupled to a first bus optical waveguide, with weaker coupling to the drop bus optical waveguide shared by the ring pair. Individual phase adjustment per optical cavity may be included in each bus optical waveguide to adjust the position of the lasing mode independently of the ring resonance. This phase tuner may provide the ability to continuously tune the optical cavity mode across a fixed range versus the discrete (optical cavity mode selection) tuning than can be achieved by thermally tuning the ring filters. Note that it may be possible to experience varying gain for the lasing modes. Therefore, each optical cavity may include a VOA that is used to increase loss in a particular optical cavity and, thus, quench lasing in a given optical cavity. Consequently, lasing may be suppressed or enhanced from one optical cavity (lasing comb) to another based at least in part on the VOA.

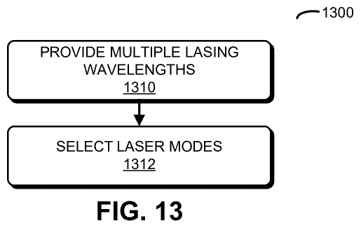

We now describe embodiments of the method. FIG. 13 is a flow diagram illustrating an example of a method 1300 for providing multiple lasing wavelengths using the optical source of FIG. 1. This optical source may include: an optical cavity comprising at least one mirror; and a semiconductor laser chip comprising multiple epitaxial gain layers. During operation, the optical source may provide, using the epitaxial gain layers that act as a gain medium, the multiple lasing wavelengths (operation 1310) in a band of wavelengths without mode hopping. Moreover, the optical source may select, using an optical component in the optical source, laser modes (operation 1312) of the optical cavity. Note that the optical component may include: an aperiodic grating; an echelle grating having a common arm that includes the epitaxial gain layers and multiple output arms that provide the lasing wavelengths; and/or a set of ring resonators that provide the lasing wavelengths.

In some embodiments of method 1300, there may be additional or fewer operations. Moreover, the order of the operations may be changed, and/or two or more operations may be combined into a single operation.

We now describe another group of embodiments of an optical source. These optical techniques may improve a multi-wavelength laser (MWL) u-comb laser where specific cavity modes of the u-comb laser can be selected to achieve a mode-selective and a tunable spacing comb. Specifically, we demonstrate a tunable mode-selective O-band quantum-dot laser that enables user-selectable longitudinal cavity modes to lase by configuring an external silicon photonic resonant cavity mirror. Using a quantum-dot gain chip with a usable gain-bandwidth of approximately 12 nm, we demonstrate stable multi-wavelength lasing on cavity modes spaced at integer multiples of the resonator free-spectral range without the use of a saturable absorber to produce up to 11 balanced lines at 200 GHz (1.1 nm) spacing or 5 balanced lines at 400 GHz (2.2 nm) spacing with side-mode suppression ratios above 50 dB, integrated RIN below 140 dB/Hz, and 6 dBm (4 mW) minimum power per line in fiber at a 6.2% power conversion efficiency from a single quantum-dot semiconductor gain stripe. Furthermore, by cavity-tuning of a 200 GHz free-spectral-range ring integrated to an inhomogeneously-broadened 1 mm quantum-dot gain chip with a 22 nm usable gain-bandwidth, we obtain 4 lines with an average fiber-coupled power above 5.2 dBm (3.3 mW) per line at a spacing of up to 1.23 THz (7 nm) with better than 45 dB side-mode suppression.

Multi-wavelength semiconductor (‘comb’) lasers present a compelling option to consolidate multiple DFB lasers into an efficient source. This integration can lead to enhanced power efficiency, a small physical footprint, simpler control circuitry, and/or high manufacturing yield. In order to provide a viable replacement for a collection of DFB lasers, a MWL typically conforms to a user-specified channel spacing with sufficient power per mode, while maintaining low RIN and minimal power variance across modes.

As a potential solution, mode-locked quantum-dot Fabry-Perot (QDFP) lasers have been demonstrated with mode spacings from a few GHz to 100 GHz. Mode-locked QDFP lasers operating in continuous-wave (CW) regimes have been reported with 89 modes with 1 mW/mode at 25 GHz spacing and RIN below-135 dB/Hz. From a user perspective, channel spacings ranging from 3.5 THz (coarse WDM) down to 100 GHz have been adopted by silicon photonic WDM link designers who balance the desire for wider separations relative to the need for narrower spacings. Wider separations enable higher modulation bandwidths, relaxed filter passband requirements, larger operating temperature ranges, and/or improved link margins. Alternatively, narrower spacings permit additional wavelength channels within the fixed passband of input/output (I/O) grating couplers or the FSR of cascaded resonant resonators. For chip-to-chip WDM communication link demonstrations, channel spacings from 200-400 GHz have been popular choices, with potentially wider spacings amenable to edge-coupled, broadband modulators.

MWL u-Comb Laser

In some of the disclosed embodiments of the optical techniques, a tunable resonator mirror design may be used to control mode spacing by selecting specific desired lasing modes while introducing tunable loss into the cavity to filter unwanted lasing modes. The laser cavity may include a QD RSOA and a silicon photonic (SiPh) external cavity with a micro-ring resonator as a mirror and filters with FSRs of 200 GHz or more. The hybrid cavity may be tuned to suppress unwanted portions of the spectrum, resulting in a low-noise MWL having the desired channel spacing without the use of a saturable absorber for passive mode-locking. This optical source may have a tunable mode spacing (between 200 GHz and 1.2 THz), low RIN (below −140 dB/Hz per line) and/or up to 49 mW output power in an optical fiber (greater than 80 mW on-chip) making the optical source a suitable candidate for tunable multi-wavelength (comb) lasers.

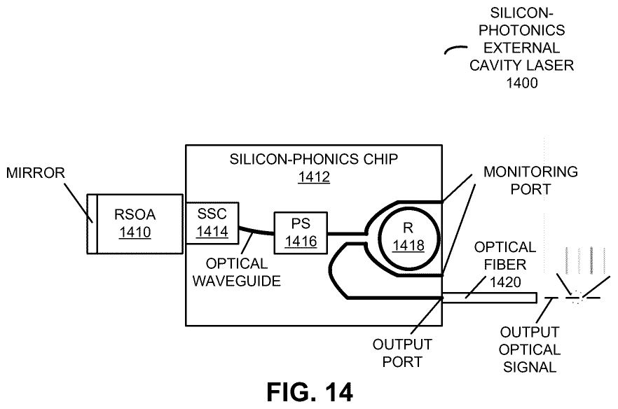

FIG. 14 presents a block diagram illustrating an example of a silicon-photonics external cavity laser 1400. In FIG. 14, an RSOA 1410 may be coupled to a silicon-photonic chip 1412 (such as SOI or SiN on SOI). Moreover, an SSC 1414 may be used to mode match to the emergent gain chip mode. Furthermore, a PS 1416 and/or a resonator tuner (such as a micro-ring resonator 1418) may provide phase-adjustment and/or resonator tuning via respective metal resistive heaters. Micro-ring resonator 1418 may target a user-specified FSR between 100 GHz and 800 GHz. Thus, silicon-photonics external cavity laser 1400 may be a MWL. Note that output power may be coupled to an optional single-mode (or polarization-maintaining) optical fiber 1420.

In some embodiments, molecular beam epitaxy (MBE)-grown QD gain chip may include ten planes of InAs/InGaAs quantum dots fabricated in a GaAs/AlGaAs active optical waveguide section. A 2.4-μm width ridge optical waveguide may be created via lithography and etching techniques. The QD RSOA may have a high reflectivity coating (greater than 99%) and an anti-reflection coated (less than 0.1%) curved output facet for edge-coupling to a silicon-photonic chip 1412. Note that silicon-photonic chip 1412 may be an external-cavity tunable mirror chip. SiN-on insulator photonic chips were designed and fabricated with edge couplers that include an SSC to match the mode of the silicon-photonic optical waveguide to the QD RSOA. The optical cavity may include a thermal phase tuner and a directional coupler to steer a fraction of power from the optical cavity to output optical fiber 1420. Micro-ring resonator 1418 may act as the second mirror of the laser and as a tunable intra-cavity filter. Micro-ring FSRs of 200 GHz and 400 GHz were implemented using SiN optical waveguides. Moreover, a thermal ring tuner may be included in silicon-photonics external cavity laser 1400. Note that silicon-photonic circuits using silicon and SiN rings have been widely studied and commercially deployed for single-wavelength, narrow-linewidth, and low-RIN tunable lasers for coherent transmission and sensing.

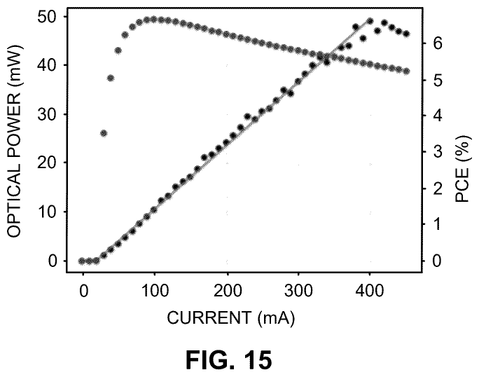

FIG. 15 provides a drawing illustrating an example of continuous-wave output power versus current, power-conversion efficiency (PCE) of a silicon-photonics external cavity laser with a 400 GHz FSR ring. Notably, FIG. 15 shows an example of light-current-PCE with a peak power in-fiber of 49 mW at 400 mA, and a peak PCE of 6.5% at 100 mA with a measured slope efficiency of 130 mW/A when coupled to the optical fiber. Equivalent on-chip (optical waveguide-coupled) PCE is greater than 10%, including tuning power, but excluding thermos-electric cooler (TEC) power.

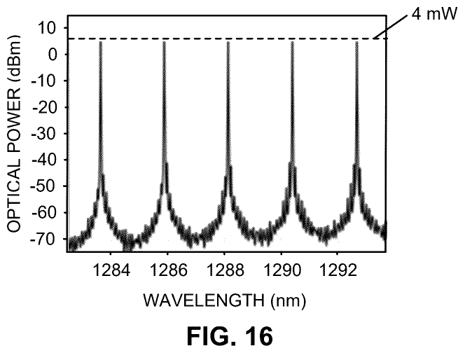

Moreover, FIG. 16 provides a drawing illustrating an example of a spectrum of the silicon-photonics external cavity laser of FIG. 15. Notably, FIG. 16 shows an example of the measured optical spectrum with a 400 GHz channel spacing and 23 mW fiber-coupled power obtained from a QD gain stripe using a high-resolution optical spectrum analyzer. Note that FIG. 16 shows a side-mode suppression ratio (SMSR) to adjacent (non-lasing) modes of 45-55 dB and 75 dB to modes between peaks.

In FIG. 15, the optical cavity was tuned to select exactly one out of every 20 cavity-modes to obtain a minimum power of 6 dBm (4 mW) and an average power of 6.6 dBm (4.6 mW) per mode at 225 mA (high-efficiency region). The output power measured from the laser increased to 49 mW at a current of 350 mA with the RSOA temperature-stabilized to 25 C. The RIN of an individually filtered laser line was measured using a 0.1 nm 3 dB passband filter and a sampling oscilloscope with a 28 Gb/s detector filtered to 15 Gb/s. The integrated RIN was determined by measuring the RMS optical power fluctuations (Pnoise) as a fraction of the average optical signal power (Psignal) integrated from DC to 15 Gb/s (fs) per the relation:

$$RIN = 10 \cdot {log}_{10} [ ( \frac{{P}_{n o i s e}}{{P}_{s i g n a l}} ) \cdot \frac{2}{( \frac{3}{4} \cdot {f}_{s} )} ] .$$

The RIN of one line was measured to be −146 dB/Hz, which include the noise contribution from a commercial driver circuit. A laser with a ring FSR of 200 GHz was similarly built and tested. Up to 11 uniform lines with 200 GHz spacing between lines were measured with a minimum of 1 mW and an average power of 2 mW fiber-coupled power per line, a peak PCE of 7.6% (excluding the TEC), and a per-line RIN of less than −135 dB/Hz.

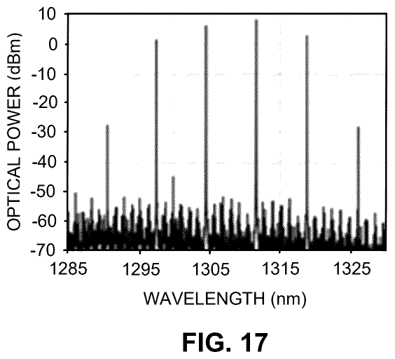

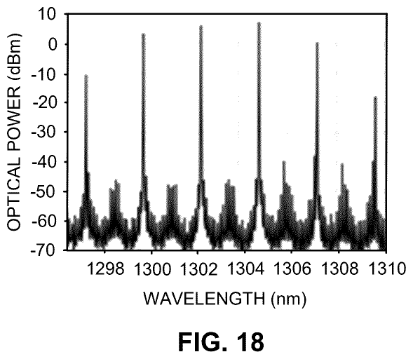

Furthermore, the wavelength-spacing tuning range was tested for a SiN ring-based external-cavity QD laser. FIGS. 17 and 18 present drawings illustrating examples of tuning ranges of the silicon-photonics external cavity laser of FIG. 15. Notably, FIG. 17 shows results from a MWL created with a 200 GHz FSR (SiN) ring coupled to a 1 mm QD RSOA having a 22 nm usable gain bandwidth. By controlling the gain current, phase shifter, and ring tuner, undesired cavity modes and filter resonances were suppressed to select lasing modes spaced wide apart (e.g., every 6th ring filter resonance corresponding to every 72^{nd} cavity mode) via Vernier tuning. 4 balanced lines above 1.5 mW per line were observed, with a total usable fiber-coupled power of 11.3 dBm (13.5 mW) at 1.23 THz (7 nm) lasing-peak spacing and a SMSR of 45-55 dB to modes associated with rejected resonant filter peaks. Similarly, FIG. 18 shows the results for a cavity tuned to 400 GHz spacing to select every 2nd ring filter resonance (corresponding to every 21^{st} cavity mode) using Vernier tuning. The SMSR was greater than 40 dB.

By independently engineering the cavity gain of a multi-layer QD gain chip and the cavity loss of a tunable external silicon photonic mirror/filter circuit, a mode-selective QD laser may be obtained that permits the selection and control of individual longitudinal lasing modes based at least in part on the configuration of the silicon photonic resonant cavity. Using a single 1 mm InAs/GaAs-based QD RSOA with an external-cavity resonant SiN mirror, a record 1.23 THz, 400 GHz, and 200 GHz spacing multi-wavelength (comb) laser was achieved with 4, 5 or 11 balanced lines and average fiber-coupled powers per line of 5.2 dBm, 6.6 dBm or 3 dBm, respectively, which were all measured at high-efficiency laser operating points. Total integrated RIN (DC to 15 Gb/s) was measured to be below-135 dB/Hz and 10 dB lower for the 400 GHz spaced lasers, respectively. The ability to dynamically vary mode spacing was demonstrated by tuning to lasing wavelength spacings of 400 GHz and 1.23 THz with a 200 GHz FSR ring. The disclosed approach uses QD SOA gain and tunable cavity mirrors in high-confinement silicon-photonics optical waveguides. This may make the near-term practical challenge one of packaging rather than process maturity, while motivating a manufacturing pathway for integrating QD gain into a photonic integrated circuit process for a uniquely tunable, widely spaced MWL.

Referring back to FIG. 14, the proposed silicon-photonics external cavity laser 1400 may include QD RSOA 1410 and an external cavity. QD RSOA 1410 may include a gain material featuring a high-reflectivity facet on one end and a low-reflectivity facet at the opposite end. The low-reflectivity facet may (or may not) have an anti-reflection coating to reduce back reflections. The low-reflectivity facet may be butt-coupled with silicon-photonic chip 1412. In some embodiments, silicon-photonic chip 1412 may be SOI, SiN or another suitable wafter platform. As noted previously, silicon-photonic chip 1412 may include SSC 1414 to match the silicon chip mode to QD RSOA 1410 to minimize coupling losses. Then, silicon-photonics external cavity laser 1400 may include an electro-optically tuned phase tuner or PS 1416, followed by a directional coupler seamlessly integrated with a tunable micro-ring resonator 1418 in an add-drop filter configuration. PS 1416 and micro-ring resonator 1418 may be tuned thermo-optically, electro-optically, and/or using another tuning technique. Note that the bottom return port may act as the output port of silicon-photonics external cavity laser 1400. Moreover, the two ports of micro-ring resonator 1418 may be monitoring ports.

During operation, as light reflects back and forth within the cavity of silicon-photonics external cavity laser 1400, it may undergo constructive interference at resonant frequencies, which correspond to the modes of silicon-photonics external cavity laser 1400. These modes may define the specific wavelengths of light that silicon-photonics external cavity laser 1400 will emit, and they may be fundamental to the operation of silicon-photonics external cavity laser 1400. The embodiments in which the micro-ring resonator is inside the optical cavity may add to or enhance a filtering effect. Notably, the micro-ring may selectively allow modes that align closely with its resonance frequency. In order to ensure that only a single mode is transmitted within each passband, the micro-ring may have a high Q-factor to achieve a narrow full-width at half-maximum (FWHM).

Note that in the silicon-photonics external cavity laser 1400, the micro-ring filter may act as a filter and a mirror. In the proposed design, the light may pass through the micro-ring only once, thereby enabling a shorter cavity and larger mode cavity spacing. As discussed further below, this may ease the alignment. This approach may be preferred to designs that use the micro-ring only as a filter and use a separate loop mirror because, in these embodiments, the light passes the micro-ring two times, setting a minimum limit on the cavity length and setting a maximum limit on the achievable separation of the cavity mode spacing.

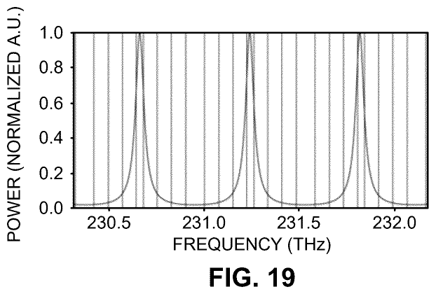

In order to achieve multiwavelength lasing, which means the laser emits several stable modes simultaneously, it may be necessary for the peak resonance of the micro-ring to be in sync with the cavity modes of the laser. Significant misalignment can lead to multiple peak lasing and a low SMSR. This is illustrated in FIG. 19, which presents a drawing illustrating an example of a laser with ring-filter resonances mis-aligned to cavity modes.

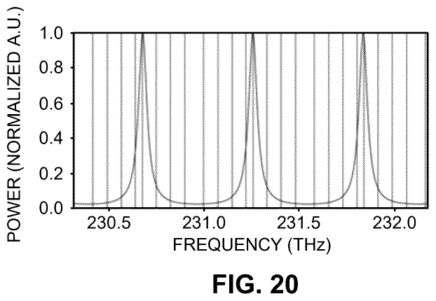

In case of sufficient alignment between cavity modes and the peak of the micro-ring filter passband, stable lasing peaks may be generated with spacings that match the FSR of the micro-ring filter. Note that the filtering may reduce low-power modes and re-enforce the stronger lasing peaks at a wavelength that correspond to the resonance wavelength of the micro-ring filter. This is illustrated in FIG. 20, which presents a drawing illustrating an example of a laser with ring-filter resonances aligned to cavity modes.

In order to align the cavity modes to the micro-ring passband, the mode spacing of the cavity may be an integer multiple of the FSR of the micro-ring filter. This may be a key requirement and condition in the disclosed optical techniques. Fabrication inaccuracies, dispersion and/or environmental factors (such as temperature variations, etc.) may prevent full alignment between cavity modes and the micro-ring filter passband. This is depicted in FIG. 19. Lines 1910 are cavity modes and curve 1912 is the spectrum of the micro-ring filter. As shown in FIG. 19, the micro-ring filter is not aligned with the cavity modes.

Moreover, in order to improve the alignment, the phase tuner or PS 1416 and micro-ring resonator 1418 may be tuned. A corrected alignment is depicted in FIG. 20. For each micro-ring passband, a single cavity mode may be aligned to it as close as possible, thereby enabling lasing modes spaced by the FSR of the micro-ring filter provided by micro-ring resonator 1418.

Note that the gain with the silicon chip external cavity may create a compound cavity that includes a Fabry-Perot resonator and a micro-ring resonator. The two resonators may create a Vernier pair that can be tuned. By properly tuning the micro-ring filter, phase tuner, chip temperature and/or gain current, the mode spacing may be adjusted to an integer multiple of the FSR of the micro-ring. For example, for a designed micro-ring with an FSR of 200 GHz, the laser may be tuned to multiple wavelengths of spacings of 200 GHz, 400 GHz, 600 GHz, 800 GHz, etc.

In some embodiments, the disclosed cavity may be expanded to include more than one tunable micro-ring filter to increase the selectivity of the laser to generate arbitrary spacings. By properly tuning the micro-ring filter, phase tuner, chip temperature and/or gain current, the power between the modes may be distributed. A set of tuning values may result in lasing lines that are equal (or approximately equal, e.g., within 1, 5 or 10%) in power. Alternatively, a set of tuning values may distribute the power unequally between the lines.

Moreover, by properly tuning the micro-ring filter, phase tuner, chip temperature and/or gain current, RIN may be significantly reduced to disclosed values for the entire laser and/or for individual lasing modes.

In the disclosed optical techniques, the micro-ring resonator device may be used to mode-lock the lasing modes by suppressing unwanted modes and re-enforcing lasing modes.

Another approach to align the cavity modes to the peak of micro-ring filter is by tuning a geometrical length of micro-ring filter, thereby tuning the FSR. The geometrical length of a micro-ring resonator may be fixed in the fabrication stage and cannot be changed later. In the present optical techniques, a variable-path add/drop filter micro-ring resonator device is included in the silicon-photonics external cavity laser. Notably, like a common add/drop filter micro-ring resonator, two optical waveguides may couple light into and from the micro-ring resonator. In some embodiments, a section of the micro-ring may be replaced with a 1-to-N selector, which may be used to route the input to one of N possible outputs. Each of the outputs may be coupled or connected to an optical waveguide with length Lₙ, where n=1 . . . . N. Note that the optical waveguide lengths may be L₁<L₂< . . . <L_{N}. Note that the end of each Lₙ optical waveguide may be routed back to the go-around optical waveguide through a N-to-1 selector.

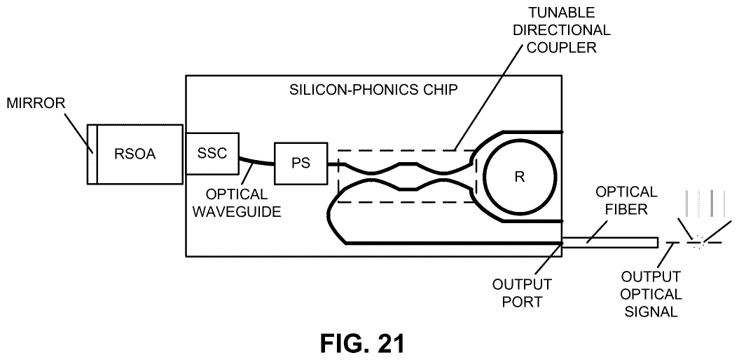

FIG. 21 provides a block diagram illustrating an example of a MWL with ring filter resonances aligned to cavity modes. This MWL may include a tunable directional coupler. By tuning the phase between the two arms of the directional coupler, the external cavity reflectivity may be tuned to adjust the amount of light return to gain and the amount of light directed to the output.

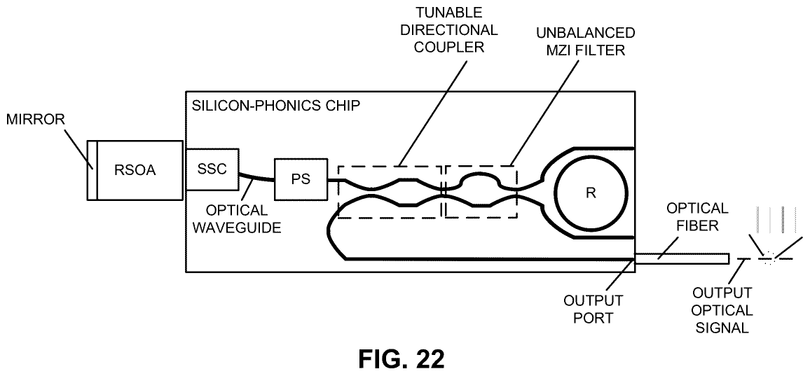

FIG. 22 provides a MWL implemented using an unbalanced Mach-Zehnder Interferometer (MZI) filter. Notably, the unbalanced MZI filter may act as an additional filter to equalize the lasing comb lines in power by providing a transfer function that imposes the opposite effect of the QD gain profile. The MZI filter may add loss to the center lasing lines, which are stronger because of the location of the peak of the gain, which causes redistribution of the gain in the cavity. Consequently, the lines farther from the center may be less attenuated by the MZI filter and the center lines may experience higher attenuation because of the MZI filter, thereby creating a power-equalized comb. Note that the MZI filter may be tunable.

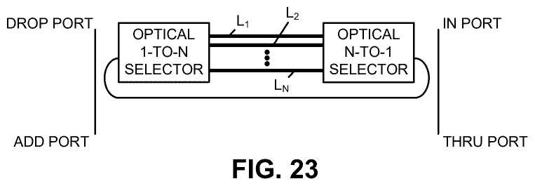

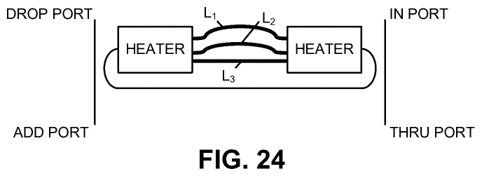

FIG. 23 presents a block diagram illustrating tuning of the FSR during operation of a MWL. Notably, by tuning the geometrical length of the resonant filter (such as the micro-ring filter), the FSR of the ring may be tuned to ensure that the micro-ring filter modes are at a multiple of the cavity modes. Note that the tuning may be a recursive process, because changing the FSR of the micro-ring and the resonance wavelengths may also affect the cavity mode spacing. FIG. 24 presents an example of an implementation of a MWL in which the 1-to-N and N-to-1 selectors are implemented using tunable 1-to-N and N-to-1 multi-mode interference couplers (such as a tunable-length micro-ring).

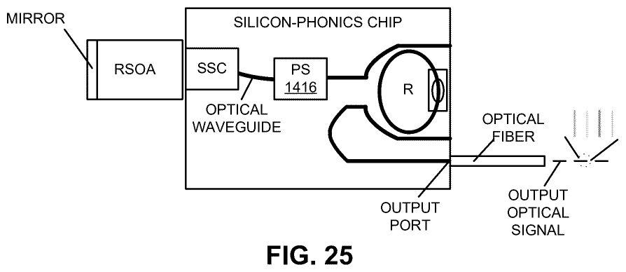

FIG. 25 presents a block diagram illustrating an example of a MWL implemented using a tunable-length micro-ring. The use of a tunable-length micro-ring may improve tunability and may increase the number of laser lines.

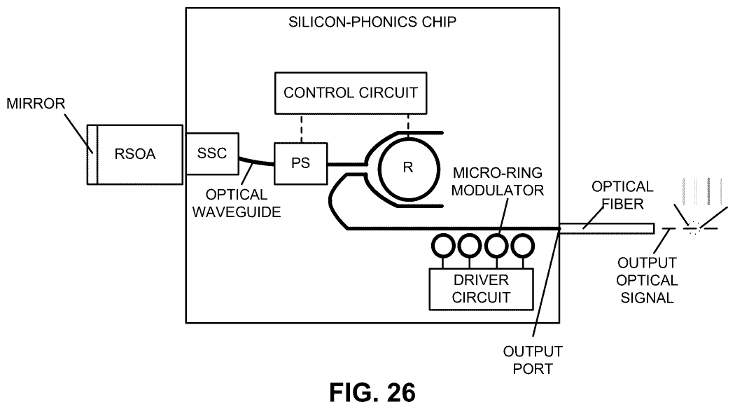

FIG. 26 presents a block diagram illustrating an example of a transmitter with a MWL and cascaded ring modulators at the output. Notably, a MWL transmitter may be implemented using a resonant modulator (such as a micro-ring modulator) following the laser output and integrated on-chip circuitry to control the phase tuner and the micro-ring filter. Each micro-ring modulator may be designed to modulate at least one wavelength of the MWL for high-speed data transmission, e.g., using binary non-return-to-zero (NRZ), pulse-amplitude-modulation four (PAM4), or another data modulation technique.

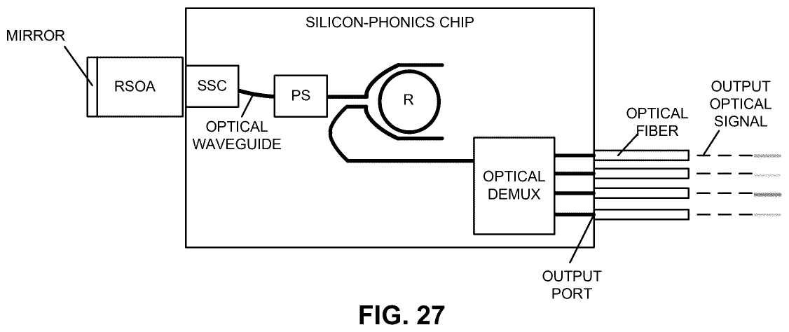

In some embodiments, a user may need to have the wavelengths in different output waveguides. FIG. 27 provides a block diagram illustrating an example of a MWL implemented using an optical demultiplexer that provides N optical outputs. Note the each of the optical outputs may have or may provide a single wavelength. Thus, the MWL may include a wavelength demultiplexer that separates wavelengths into a set of optical waveguides.

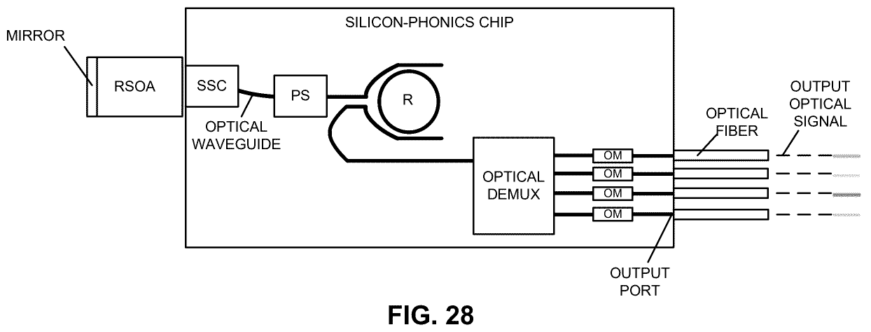

FIG. 28 presents a block diagram illustrating an example of a transmitter with a MWL implemented using an optical demultiplexer that provides N optical outputs. Note the each of the optical outputs may have or may provide a single wavelength, followed by an optical modulator (OM) on each output arm that modulates individual wavelengths. The optical modulator may be: a micro-ring modulator, a Mach-Zehnder modulator, or an electro-absorption modulator.

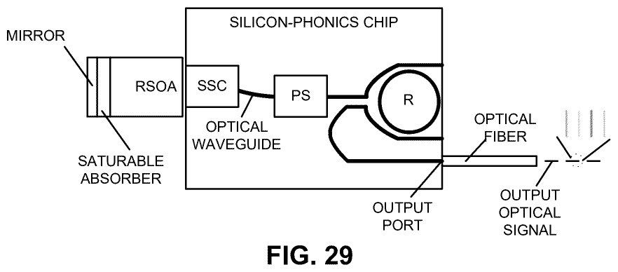

In some embodiments, the use of a saturable absorber may help mode-lock the chosen lasing modes to create an equally spaced low-noise, MWL. As shown in FIG. 29, which presents a block diagram illustrating an example of a MWL, a saturable absorber may be added to the gain chip (such as the RSOA) to mode-lock the MWL.

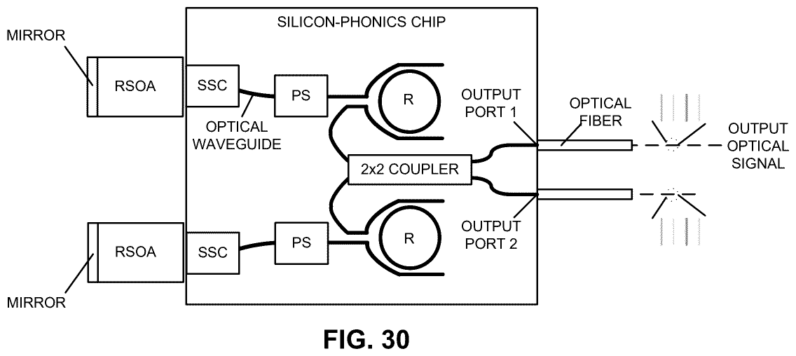

FIG. 30 presents a block diagram illustrating an example of a dual MWL. Notably, two RSOA gains, which can be either separate or on a dual-array configuration (shared die), may be coupled to two external cavities. The output of the two MWLs may be combined to create two copies of the combined laser. Moreover, a tunable directional coupler in the dual MWL may steer power and wavelength between the two outputs. This configuration may generate a broader comb with a larger number of wavelengths, assuming the gain bandwidth of the RSOA permits. Moreover, the configuration of FIG. 30 may also be used to interleave the combs.

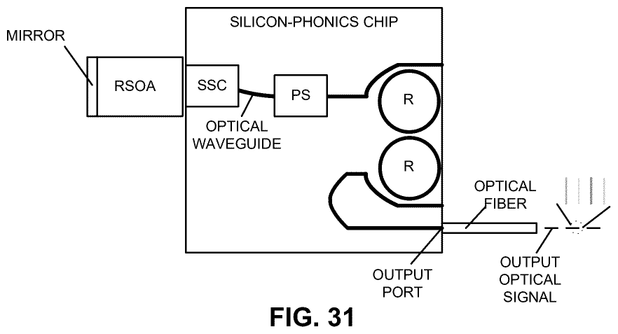

Furthermore, FIG. 31 provides a block diagram illustrating an example of a Vernier MWL. Notably, the Vernier MWL may have a tunable spacing using dual micro-ring resonators of different radii. In FIG. 31, a single gain may feed a cavity with a tunable phase tuner and two tunable micro-ring resonators. By properly designing the radii of the micro-ring resonators to make a Vernier pair, the MWL may generate very large spacings. Note that the spacings may be otherwise limited by the FSR of a single micro-ring resonator, which may be limited by the minimum practical radius of a single micro-ring resonator.

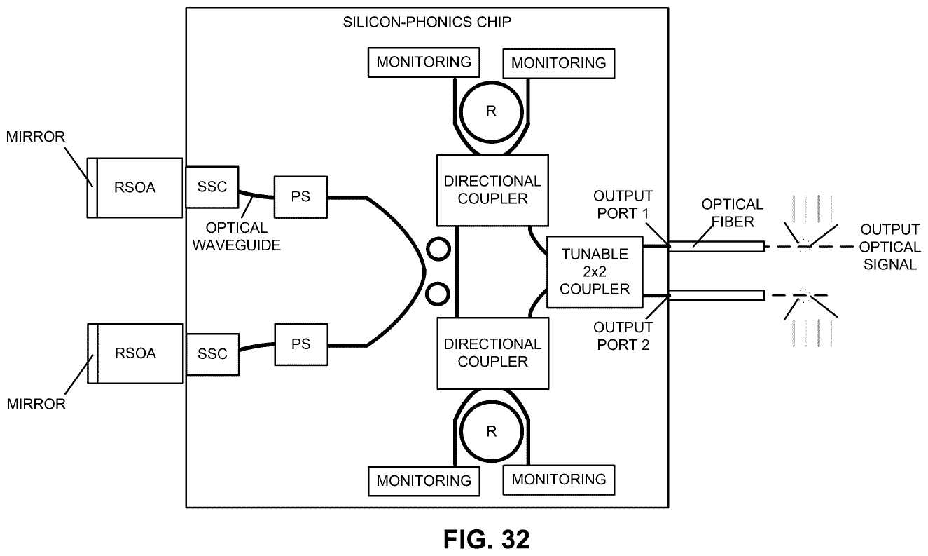

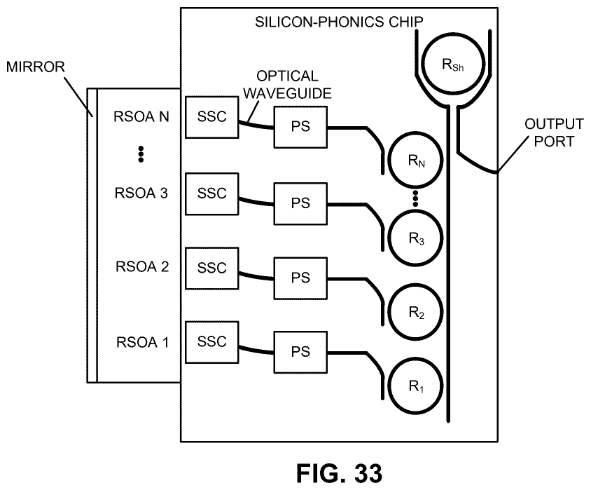

In some embodiments, more than one gain-chip may be used in a consolidated MWL configuration. FIG. 32 provides a block diagram illustrating an example of a dual-gain Vernier MWL having a tunable spacing. In FIG. 32, two gains may feed a combined cavity. A pair of micro-ring resonators, having large and small micro-rings, may tune the spacing of a comb. The comb from the two gains may be combined with a tunable 2×2 directional coupler. The smaller micro-rings may also have slightly different radii, which may enable each smaller micro-ring to choose a different lasing mode within the allowable resonant passbands of the larger micro-ring. Note that more than two smaller micro-rings may be cascaded on a first bus. This approach may be used to extend the workable bandwidth of the MWL, increase number of lines, achieve customized spacings, etc. The configuration in FIG. 32 may be extended to combine N combs. This is shown in FIG. 33, which provides a block diagram illustrating an example of a Vernier MWL with multiple RSOAs having a tunable spacing.

The preceding embodiments may include additional or fewer components. Moreover, positions of one or more components may be changed, two or more components may be combined into a single component and/or a component may be divided into two or more components.

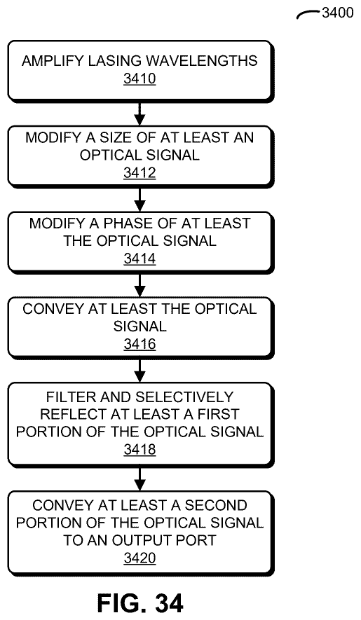

We now describe embodiments of the method. FIG. 34 is a flow diagram illustrating an example of a method 3400 for providing multiple lasing wavelengths using an optical source, such as the optical source in FIG. 14. This optical source may include: a semiconductor laser chip providing a gain medium in a first portion of an optical cavity, and at least a first mirror; and a silicon-photonics chip providing a second portion of the optical cavity. During operation, the semiconductor laser chip amplifies the lasing wavelengths (operation 3410) in a band of wavelengths. Then, modify a size of at least an optical signal (operation 3412) corresponding to the lasing wavelengths using a spot-size converter in the silicon-photonics chip, where the spot-size converter is proximate to an interface between the semiconductor laser chip and the silicon-photonics chip. Moreover, modify a phase of at least the optical signal (operation 3414) using a phase selector in the silicon-photonics chip. Next, convey at least the optical signal (operation 3416) to a micro-ring resonator using a first optical waveguide in the silicon-photonics chip. Furthermore, filter and selectively reflect a first portion of at least the optical signal (operation 3418) using the micro-ring resonator, where resonance frequencies of the micro-ring resonator match optical modes of the optical cavity or a non-zero integer multiple of the optical modes. Additionally, convey a second portion of at least the optical signal to an output port of the optical source (operation 3420) using a second optical waveguide, where the second portion of at least the optical signal includes the lasing wavelengths.

In some embodiments of method 3400, there may be additional or fewer operations. Moreover, the order of the operations may be changed, and/or two or more operations may be combined into a single operation.

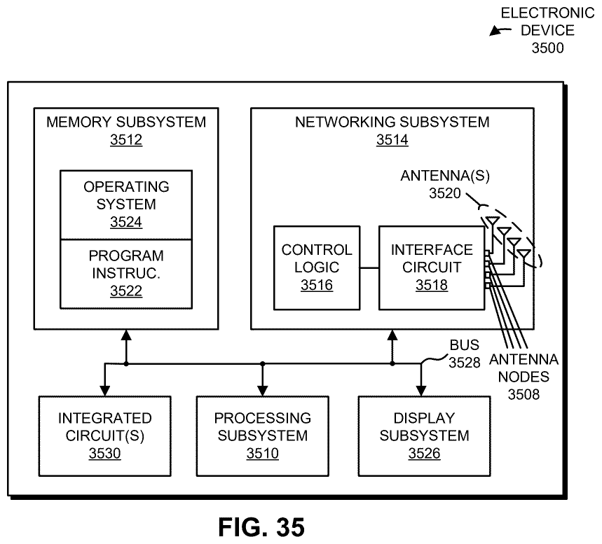

We now describe embodiments of an electronic device, which may perform at least some of the operations in the measurement techniques. FIG. 35 presents a block diagram illustrating an example of an electronic device 3500 (or one or more electronic devices). This electronic device includes processing subsystem 3510, memory subsystem 3512, and networking subsystem 3514. Note that one or more of these subsystems may include at least an instance of one of the previous embodiments of the optical source, such as the integrated circuit in FIG. 2.

Processing subsystem 3510 includes one or more devices configured to perform computational operations. For example, processing subsystem 3510 can include one or more: microprocessors, ASICs, microcontrollers, programmable-logic devices, graphics processing units (GPUs) and/or digital signal processors (DSPs).

Memory subsystem 3512 includes one or more devices for storing data and/or instructions for processing subsystem 3510 and networking subsystem 3514. For example, memory subsystem 3512 can include dynamic random access memory (DRAM), static random access memory (SRAM), and/or other types of memory. In some embodiments, instructions for processing subsystem 3510 in memory subsystem 3512 include: one or more program instructions or sets of instructions (such as program instructions 3522 or operating system 3524), which may be executed by processing subsystem 3510. Note that the one or more computer programs may constitute a computer-program mechanism. Moreover, instructions in the various modules in memory subsystem 3512 may be implemented in: a high-level procedural language, an object-oriented programming language, and/or in an assembly or machine language. Furthermore, the programming language may be compiled or interpreted, e.g., configurable or configured (which may be used interchangeably in this discussion), to be executed by processing subsystem 3510.

In addition, memory subsystem 3512 can include mechanisms (such as a circuit or software) for controlling access to the memory. In some embodiments, memory subsystem 3512 includes a memory hierarchy that comprises one or more caches coupled to a memory in electronic device 3500. In some of these embodiments, one or more of the caches is located in processing subsystem 3510.

In some embodiments, memory subsystem 3512 is coupled to one or more high-capacity mass-storage devices (not shown). For example, memory subsystem 3512 can be coupled to a magnetic or optical drive, a solid-state drive, or another type of mass-storage device. In these embodiments, memory subsystem 3512 can be used by electronic device 3500 as fast-access storage for often-used data, while the mass-storage device is used to store less frequently used data.

Networking subsystem 3514 includes one or more devices configured to couple to and communicate on a wired and/or wireless network (i.e., to perform network operations), including: control logic 3516, an interface circuit 3518 and one or more optional antennas 3520 (or antenna elements). (While FIG. 35 includes one or more antennas 3520, in some embodiments electronic device 3500 includes one or more nodes, such as antenna nodes 3508, e.g., a connector or a pad, which can be coupled to the one or more antennas 3520. Thus, electronic device 3500 may or may not include the one or more antennas 3520.) For example, networking subsystem 3514 can include a Bluetooth™ networking system, a cellular networking system (e.g., a 3G/4G/5G network such as UMTS, LTE, etc.), a universal serial bus (USB) networking system, a networking system based on the standards described in IEEE 802.11 (e.g., a Wi-Fi® networking system), an Ethernet networking system, and/or another networking system.

Networking subsystem 3514 includes processors, controllers, radios/antennas, sockets/plugs, and/or other devices used for coupling to, communicating on, and handling data and events for each supported networking system. Note that mechanisms used for coupling to, communicating on, and handling data and events on the network for each network system are sometimes collectively referred to as a ‘network interface’ for the network system. Moreover, in some embodiments a ‘network’ or a ‘connection’ between the electronic devices does not yet exist. Therefore, electronic device 3500 may use networking subsystem 3514 for performing simple wireless communication, e.g., transmitting advertising or beacon frames and/or scanning for advertising frames transmitted by other electronic devices.

Within electronic device 3500, processing subsystem 3510, memory subsystem 3512, networking subsystem 3514 and optional integrated circuit(s) 3530 are coupled together using signal lines, links or bus 3528. These connections may include an electrical, optical, and/or electro-optical connection that the subsystems can use to communicate signals, commands and data among one another.

Furthermore, while some components are shown directly connected to one another in FIG. 35, in general coupling can also occur via intermediate components. In each instance, the method of interconnection, or ‘coupling,’ establishes some desired communication between two or more circuit nodes, or terminals. Such coupling may often be accomplished using a number of circuit configurations, as will be understood by those of skill in the art; for example, AC coupling and/or DC coupling may be used. Although only one bus 3528 (or one or more signal lines) is shown for clarity in FIG. 35, different embodiments can include a different number or configuration of electrical, optical, and/or electro-optical connections among the subsystems.

In some embodiments, electronic device 3500 includes a display subsystem 3526 for displaying information on a display, which may include a display driver and the display, such as a liquid-crystal display, a multi-touch touchscreen, etc.

Electronic device 3500 and/or an instance of the integrated circuit may include: a VLSI circuit, a switch, a hub, a bridge, a router, a communication system (such as a wavelength-division-multiplexing communication system), a storage area network, a data center, a network (such as a local area network), and/or a computer system (such as a multiple-core processor computer system). Furthermore, the computer system and/or an instance of the integrated circuit may include, but is not limited to: a desktop computer, a server (such as a multi-socket, multi-rack server), a laptop computer, a communication device or system, an access point, a router, a switch, communication equipment, a controller, test equipment, a personal computer, a work station, a mainframe computer, a blade, an enterprise computer, a data center, a tablet computer, a supercomputer, a network-attached-storage (NAS) system, a storage-area-network (SAN) system, a media player, an appliance, a subnotebook/netbook, a tablet computer, a smartphone, a cellular telephone, a smartwatch, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, a sensor (such as a LIDAR sensor), an automobile or a truck, another electronic device, a laser (such as a hybrid laser) and/or another optical component.

Although specific components are used to describe electronic device 3500, in alternative embodiments, different components and/or subsystems may be present in electronic device 3500. For example, electronic device 3500 may include one or more additional processing subsystems, memory subsystems, networking subsystems, display subsystems and/or one or more additional subsystems not shown in FIG. 35 (such as a user-input subsystem). Additionally, one or more of the subsystems may not be present in electronic device 3500. Also, although separate subsystems are shown in FIG. 35, in some embodiments some or all of a given subsystem or component can be moved or integrated into one or more of the other subsystems or component(s) in electronic device 3500. For example, in some embodiments program instructions 3522 are included in operating system 3524 and/or control logic 3516 is included in interface circuit 3518. Thus, while electronic device 3500, as well as the previous embodiments of the integrated circuit, are illustrated as having a number of discrete items, these components are intended to be functional descriptions of the various features that may be present rather than structural schematics of the embodiments described herein.

Moreover, the circuits and components in electronic device 3500 may be implemented using any combination of analog and/or digital circuitry, including: bipolar, PMOS and/or NMOS gates or transistors. Furthermore, signals in these embodiments may include digital signals that have approximately discrete values and/or analog signals that have continuous values. Additionally, components and circuits may be single-ended or differential, and power supplies may be unipolar or bipolar.

An integrated circuit may implement some or all of the functionality of electronic device 3500. In some embodiments, an output of a process for designing the integrated circuit, or a portion of the integrated circuit, which includes one or more of the circuits described herein may be a computer-readable medium such as, for example, a magnetic tape or an optical or magnetic disk. The computer-readable medium may be encoded with data structures or other information describing circuitry that may be physically instantiated as the integrated circuit or the portion of the integrated circuit. Although various formats may be used for such encoding, these data structures are commonly written in: Caltech Intermediate Format (CIF), Calma GDS II Stream Format (GDSII), Electronic Design Interchange Format (EDIF), OpenAccess (OA), or Open Artwork System Interchange Standard (OASIS). Those of skill in the art of integrated circuit design can develop such data structures from schematics of the type detailed above and the corresponding descriptions and encode the data structures on the computer-readable medium. Those of skill in the art of integrated circuit fabrication can use such encoded data to fabricate integrated circuits that include one or more of the circuits described herein.

While some of the operations in the preceding embodiments were implemented in hardware or software, in general the operations in the preceding embodiments can be implemented in a wide variety of configurations and architectures, such as by one or more: ASICs, FPGAs, DPSs, GPUs, etc. Therefore, some or all of the operations in the preceding embodiments may be performed in hardware, in software or both. For example, at least some of the operations in the measurement techniques may be implemented using program instructions 3522, operating system 3524 (such as a driver for interface circuit 3518) or in firmware in interface circuit 3518. Alternatively or additionally, at least some of the operations in the measurement techniques may be implemented in a physical layer, such as hardware in interface circuit 3518. In general, electronic device 3500 may be at one location or may be distributed over multiple, geographically dispersed locations.

Moreover, the preceding embodiments of the integrated circuit and/or electronic device 3500 can be used in a wide variety of applications, such as: communications (for example, in a transceiver, an optical source (such as a laser), an optical interconnect or an optical link, such as for intra-chip or inter-chip communication), a radio-frequency filter, a bio-sensor, data storage (such as an optical-storage device or system), medicine (such as a diagnostic technique or surgery), a barcode scanner, metrology (such as precision measurements of distance), manufacturing (cutting or welding), a lithographic process, data storage (such as an optical-storage device or system) and/or entertainment (a laser light show).

While the preceding embodiments have been illustrated with particular elements and compounds, a wide variety of materials and compositions (including stoichiometric and non-stoichiometric compositions) may be used, as is known to one of skill in the art. Thus, while a silicon optical waveguide was illustrated in some of the preceding embodiments, the measurement techniques may be used with other materials (such as germanium, silicon germanium, glass and/or plastic), as is known to one of skill in the art. Moreover, the layer may include polysilicon or amorphous silicon. Furthermore, the materials and compounds in the embodiments of the integrated circuit may be fabricated using a wide variety of processing techniques, including: evaporation, sputtering, chemical vapor deposition, molecular-beam epitaxy, wet or dry etching (such as photolithography or direct-write lithography), polishing, etc. In addition, a wide variety of optical components may be used in or in conjunction with one or more of the embodiments of the integrated circuit. Furthermore, a wide variety of optical sources may be integrated with or included in one or more of the embodiments of the integrated circuit, including many different types of lasers or non-laser optical sources (such as a light-emitting diode).

Note that the use of the phrases ‘capable of,’ ‘capable to,’ ‘operable to,’ or ‘configured to’ in one or more embodiments, refers to some apparatus, logic, hardware, and/or element designed in such a way to enable use of the apparatus, logic, hardware, and/or element in a specified manner.

Moreover, while the preceding discussion included some numerical values, these values are for purposes of illustration and are not intended to be limiting. In other embodiments, different numerical values may be used.

In the preceding description, we refer to ‘some embodiments.’ Note that ‘some embodiments’ describes a subset of all of the possible embodiments, but does not always specify the same subset of embodiments.

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. An optical source, comprising:
a semiconductor laser chip, comprising:
a gain medium in a first portion of an optical cavity, wherein the gain medium is configured to provide multiple lasing wavelengths in a band of wavelengths; and
at least a first mirror;
a silicon-photonics chip optically coupled to the semiconductor laser chip, wherein the silicon-photonics chip provides a second portion of the optical cavity, wherein the silicon-photonics chip comprises: a first optical waveguide with a spot-size converter proximate to an interface between the semiconductor laser chip and the silicon-photonics chip; and a phase shifter that provides phase adjustment to an optical signal in the optical cavity; and
a micro-ring resonator optically coupled to the first optical waveguide and a second optical waveguide, wherein the micro-ring resonator is configured to provide resonant tuning of the optical source, and is configured to provide an optical filter and a second mirror in the optical cavity, and wherein the second optical waveguide is configured to convey an output optical signal from the micro-ring resonator to an output port of the optical source.

2. The optical source of claim 1, wherein the semiconductor laser chip comprises a III-V semiconductor; and the silicon-photonics chip comprises: silicon-on-insulator (SOI) or silicon nitride (SiN) on SOI.

3. The optical source of claim 1, wherein the micro-ring resonator has a free-spectral range (FSR) between 100 GHz and 800 GHz.

4. The optical source of claim 1, wherein a phase of the phase shifter is adjusted using a first resistive heater or electro-optic tuning; and/or resonance frequencies of the micro-ring resonator are adjusted using a second resistive heater or electro-optic tuning.

5. The optical source of claim 4, wherein the resonance frequencies are adjusted to match modes of the optical cavity.

6. The optical source of claim 1, wherein the optical source comprises a tunable feedback element optically coupling the first optical waveguide and the second optical waveguide.

7. The optical source of claim 6, wherein the optical source comprises a second optical filter between the tunable feedback element and the micro-ring resonator, and wherein the optical filter comprises a Mach-Zehnder Interferometer (MZI).

8. The optical source of claim 1, wherein the optical source comprises a 1-to-N optical selector and an N-to-1 optical selector optically coupled to the first optical waveguide and the second optical waveguide.

9. The optical source of claim 8, wherein the 1-to-N optical selector, the N-to-1 optical selector, or both, implemented using a tunable multi-mode interference coupler.

10. The optical source of claim 1, wherein the micro-ring resonator is configured to perform resonant filtering, modulation or both of the optical signal.

11. The optical source of claim 1, wherein an optical demultiplexer is optically coupled to the second optical waveguide.

12. The optical source of claim 11, wherein the optical demultiplexer comprises a set of micro-ring resonators configured to provide the lasing wavelengths.

13. The optical source of claim 11, wherein the optical demultiplexer is configured to provide a set of parallel output ports that each provide a single lasing wavelength in the lasing wavelengths;
wherein each of the output ports comprises an optical modulator; and
wherein the optical modulator comprises: a micro-ring modulator, a Mach-Zehnder modulator, or an electro-absorption modulator.

14. The optical source of claim 1, wherein the semiconductor laser chip comprises a saturable absorber.

15. The optical source of claim 1, wherein the optical source comprises a second micro-ring resonator, and the micro-ring resonator and the second micro-ring resonator provide a Vernier.

16. The optical source of claim 1, wherein the optical source comprises: multiple instances of the semiconductor laser chip, located on a common or different substrates; the first optical waveguide; the spot-size converter; the phase shifter; and the micro-ring resonator;
wherein each of the instances of the semiconductor laser chip corresponds to different lasing wavelength in the lasing wavelengths; and
wherein the optical source comprises an output micro-ring resonator optically coupled to the second optical waveguide.

17. The optical source of claim 1, wherein the lasing wavelengths are tunable.

18. The optical source of claim 1, wherein a free-spectral range (FSR) of the optical source is tuned by switching between round-trip lengths of the optical signal in the optical cavity.

19. An electronic device, comprising an optical source, wherein the optical source comprises:
a semiconductor laser chip, comprising:
a gain medium in a first portion of an optical cavity, wherein the gain medium is configured to provide multiple lasing wavelengths in a band of wavelengths; and
at least a first mirror;
a silicon-photonics chip optically coupled to the semiconductor laser chip, wherein the silicon-photonics chip provides a second portion of the optical cavity, wherein the silicon-photonics chip comprises: a first optical waveguide with a spot-size converter proximate to an interface between the semiconductor laser chip and the silicon-photonics chip; and a phase shifter that provides phase adjustment to an optical signal in the optical cavity; and
a micro-ring resonator optically coupled to the first optical waveguide and a second optical waveguide, wherein the micro-ring resonator is configured to provide resonant tuning of the optical source, and is configured to provide an optical filter and a second mirror in the optical cavity, and wherein the second optical waveguide is configured to convey an output optical signal from the micro-ring resonator to an output port of the optical source.

20. A method for providing multiple lasing wavelengths, comprising:
by an optical source:
amplifying multiple lasing wavelengths in a band of wavelengths using a semiconductor laser chip having: a gain medium in a first portion of an optical cavity, and at least a first mirror;
modifying a size of one or more optical signals corresponding to the lasing wavelengths using a spot-size converter in a silicon-photonics chip, wherein the spot-size converter is proximate to an interface between the semiconductor laser chip and the silicon-photonics chip, and wherein the silicon-photonics chip provides a second portion of the optical cavity;
adjusting a phase of at least an optical signal using a phase selector in the silicon-photonics chip;
conveying at least the optical signal to a micro-ring resonator using a first optical waveguide in the silicon-photonics chip;
filtering and selectively reflecting a first portion of at least the optical signal using the micro-ring resonator, wherein resonance frequencies of the micro-ring resonator match optical modes of the optical cavity or a non-zero integer multiple of the optical modes; and
conveying a second portion of at least the optical signal to an output port of the optical source using a second optical waveguide, wherein the second portion of at least the optical signal comprises the lasing wavelengths.
